(19) United States
(12) Patent Application Publication
(10) Pub. No.: US 2024/0146259 A1
(43) Pub. Date: May 2, 2024

(54) POWER AMPLIFIER CIRCUIT AND POWER AMPLIFICATION METHOD

(71) Applicant: Murata Manufacturing Co., Ltd., Nagaokakyo-shi (JP)

(72) Inventors: Kenji TAHARA, Nagaokakyo-shi (JP); Kae YAMAMOTO, Nagaokakyo-shi (JP)

(73) Assignee: Murata Manufacturing Co., Ltd., Nagaokakyo-shi (JP)

(21) Appl. No.: 18/408,627

(22) Filed: Jan. 10, 2024

Related U.S. Application Data
(63) Continuation of application No. PCT/JP2022/027540, filed on Jul. 13, 2022.

(30) Foreign Application Priority Data
Jul. 15, 2021 (JP) 2021-116817

(51) Int. Cl. H03F 3/24

(52) U.S. Cl. CPC H03F 3/245; H03F 2200/451

(57) ABSTRACT

A power amplifier circuit includes a power amplifier and an external power terminal that receives a power supply voltage from a power supply circuit. The power amplifier includes two amplifying elements and, a limiter, and an RC circuit. The amplifying elements respectively include first and second input terminals, first and second output terminals, and first and second power terminals. The limiter restricts the power supply voltage to a predetermined range and outputs the restricted power supply voltage. The RC circuit is connected in parallel with the limiter. The first input terminal is connected to an external input terminal. The first output terminal is connected to the second input terminal. The second output terminal is connected to an external output terminal. The first power terminal is connected to the external power terminal via the limiter. The second power terminal is connected to the external power terminal.

### CROSS-REFERENCE TO RELATED APPLICATIONS

This application is a continuation of international application no. PCT/JP2022/027540, filed Jul. 13, 2022, and which claims priority to Japanese application no. JP 2021-116817, filed Jul. 15, 2021. The entire contents of both prior applications are hereby incorporated by reference.

### TECHNICAL FIELD

The present disclosure relates to a power amplifier circuit and a power amplification method.

### BACKGROUND ART

These days, power amplification efficiency is being improved by varying a power supply voltage to be supplied to a power amplifier circuit. An analog ET (Envelope Tracking) technology for supplying a power supply voltage of a continuously changing voltage level and an average power tracking (APT) technology for supplying a power supply voltage of multiple discrete voltage levels, for example, are known.

### CITATION LIST

### Patent Document

Patent Document 1: U.S. Patent Application Publication No. 2020/0076375

### SUMMARY

### Technical Problem

However, if the gain of a power amplifier circuit is shifted due to the varying of a power supply voltage to be supplied to the power amplifier circuit, the quality of a radio-frequency signal output from the power amplifier circuit may be degraded.

The present disclosure provides a power amplifier circuit and a power amplification method that can reduce the quality degradation of a radio-frequency output signal, which is caused by varying a power supply voltage to be supplied to the power amplifier circuit.

### Solution to Problem

A power amplifier circuit according to an aspect of the disclosure includes an external input terminal, an external output terminal, a power amplifier, and at least one external power supply terminal. The at least one external power supply terminal receives from a power supply circuit a power supply voltage to be supplied to the power amplifier. The power amplifier includes first and second amplifying elements, a first circuit, and a first RC series circuit. The first amplifying element has a first input terminal, a first output terminal, and a first power supply terminal. The second amplifying element has a second input terminal, a second output terminal, and a second power supply terminal. The first circuit restricts the power supply voltage to a predetermined range and outputs the restricted power supply voltage. The first RC series circuit is connected in parallel with the first circuit. The first input terminal is connected to the external input terminal. The first output terminal is connected to the second input terminal. The second output terminal is connected to the external output terminal. The first power supply terminal is connected to the at least one external power supply terminal via the first circuit. The second power supply terminal is connected to the at least one external power supply terminal.

A power amplifier circuit according to an aspect of the disclosure includes an external input terminal, an external output terminal, a power amplifier, and at least one external power supply terminal. The at least one external power supply terminal receives from a power supply circuit a power supply voltage to be supplied to the power amplifier. The power amplifier includes first and second amplifying elements, a first circuit, and a first RC series circuit. The first amplifying element has a first input terminal, a first output terminal, and a first power supply terminal. The second amplifying element has a second input terminal, a second output terminal, and a second power supply terminal. The first RC series circuit is connected in parallel with the first circuit. The first input terminal is connected to the external input terminal. The first output terminal is connected to the second input terminal. The second output terminal is connected to the external output terminal. The first power supply terminal is connected to the at least one external power supply terminal via the first circuit. The second power supply terminal is connected to the at least one external power supply terminal. The first circuit includes a third amplifying element, a transistor, and a feedback circuit. The third amplifying element has a third input terminal and a third output terminal. The transistor has a control terminal connected to the third output terminal and is connected between the at least one external power supply terminal and the first power supply terminal. The feedback circuit is connected between the first power supply terminal and the third input terminal.

A power amplification method according to an aspect of the disclosure includes: a first circuit restricting a power supply voltage received from a power supply circuit to a predetermined range, an RC series circuit being connected in parallel with the first circuit, and supplying the restricted power supply voltage to a first amplifying element; the first amplifying element amplifying a radio-frequency signal by using the power supply voltage received from the first circuit; and a second amplifying element amplifying the radio-frequency signal amplified by the first amplifying element by using the power supply voltage received from the power supply circuit.

### Exemplary Advantageous Effects

According to the present disclosure, it is possible to reduce the quality degradation of a radio-frequency output signal, which is caused by varying a power supply voltage to be supplied to a power amplifier circuit.

### BRIEF DESCRIPTION OF DRAWINGS

FIG. 1 is a circuit diagram of a radio-frequency module and a communication device according to a first exemplary embodiment.

FIG. 2 is a circuit diagram of a power amplifier circuit according to the first exemplary embodiment.

FIG. 3A is a graph illustrating an example of the transition of a power supply voltage in an analog ET mode.

FIG. 3B is a graph illustrating an example of the transition of a power supply voltage in an APT mode.

FIG. 4 is a sequence diagram illustrating an operation of the communication device according to the first exemplary embodiment.

FIG. 5A is a graph illustrating the gain characteristics when a voltage limiter circuit is in the OFF state.

FIG. 5B is a graph illustrating the gain characteristics when the voltage limiter circuit is in the ON state.

FIG. 6 is a graph illustrating an example of variations of the power supply voltage when an RC series circuit is provided and those when the RC series circuit is not provided.

FIG. 7 is a circuit diagram of a power amplifier circuit and a power supply circuit according to a second exemplary embodiment.

FIG. 8 is a table illustrating the operation of the power amplifier circuit according to the second exemplary embodiment.

FIG. 9A is a circuit diagram of the power amplifier circuit operating in the APT mode.

FIG. 9B is a circuit diagram of the power amplifier circuit operating in the analog ET mode.

FIG. 10 is a graph illustrating the gain characteristics of the power amplifier circuit operating in the analog ET mode.

FIG. 11 is a circuit diagram of a power amplifier circuit according to a third exemplary embodiment.

FIG. 12 is a table illustrating the operation of the power amplifier circuit according to the third exemplary embodiment.

FIG. 13 is a circuit diagram of a power amplifier circuit according to a modified example of the third exemplary embodiment.

FIG. 14 is a table illustrating the operation of the power amplifier circuit according to the modified example of the third exemplary embodiment.

FIG. 15A is a plan view of a radio-frequency module according to a first example.

FIG. 15B is a plan view of the radio-frequency module according to the first example.

FIG. 16 is a sectional view of the radio-frequency module according to the first example.

FIG. 17 is a plan view illustrating part of a radio-frequency module according to a second example.

### DETAILED DESCRIPTION

Power amplifier circuits and power amplification methods according to exemplary embodiments of the disclosure will be described below in detail with reference to the drawings. All the exemplary embodiments described below illustrate specific examples. Numerical values, configurations, materials, elements, positions and connection states of the elements, steps, and the order of steps illustrated in the following exemplary embodiments are only examples and are not intended to limit the disclosure. Among the elements illustrated in the following exemplary embodiments, the elements that are not recited in the independent claims will be described as optional elements.

The drawings are only schematically shown and are not necessarily precisely illustrated. For example, the reduced scales in the individual drawings do not necessarily match each other. In the individual drawings, elements having the substantially same configuration are designated by like reference numeral and an explanation thereof will be simplified or not be repeated from the second time.

In the specification, terms representing the relationship between elements, such as being parallel and being vertical, terms representing the shape of an element, such as being rectangular, and ranges of numerical values are not necessarily to be interpreted in an exact sense, but to be interpreted in a broad sense. That is, such terms and ranges also cover substantially equivalent ranges, such as about several percent of allowance.

In the circuit configurations of the disclosure, “A is connected to B” includes, not only the meaning that A is directly connected to B using a connection terminal and/or a wiring conductor, but also the meaning that A is electrically connected to B via another circuit element. “An element is connected between A and B” means that the element is connected to both A and B between A and B and includes the meaning that the element is connected in series with a path connecting A and B and also that the element is connected (shunt-connected) between this path and a ground.

In the specification and the drawings, the x axis, y axis, and z axis are the three axes of a three-dimensional Cartesian coordinate system.

In the layout of components in the disclosure, “in a plan view of a module laminate” is synonymous with “in a plan view of a main surface of a module laminate” and means that an object is orthographically projected on an xy plane from the positive side of the z axis and is viewed from this side. In the specification, “in a plan view” means “in a plan view of a main surface of a module laminate” unless otherwise stated.

“A component is disposed on a main surface of a module laminate” includes the meaning that the component is disposed on the main surface of the module laminate while being in contact with the main surface, and also includes the meaning that the component is disposed over the main surface without contacting it and that the component is partially embedded in the module laminate from the main surface. “A overlaps or matches B in a plan view” means that a region of A orthographically projected on the xy plane overlaps or matches a region of B orthographically projected on the xy plane. “A is disposed between B and C” means that at least one of line segments connecting a certain point within B and a certain point within C passes through A.

In the specification, ordinal numbers, such as “first” and “second”, do not designate the number of elements or the order of elements unless otherwise stated, but are used for distinguishing elements of the same type from each other.

In the specification, “transmit path” means a transmission line constituted by wiring for transferring a radio-frequency transmission signal, an electrode directly connected to the wiring, and a terminal directly connected to the wiring or the electrode, for example. In the specification, “receive path” means a transmission line constituted by wiring for transferring a radio-frequency reception signal, an electrode directly connected to the wiring, and a terminal directly connected to the wiring or the electrode, for example. “Transmit/receive path” means a transmission line constituted by wiring for transferring both of a radio-frequency transmission signal and a radio-frequency reception signal, an electrode directly connected to the wiring, and a terminal directly connected to the wiring or the electrode, for example.

### First Embodiment

### 1.1 Circuit Configurations of Communication Device 7, Radio-Frequency Module 6, and Power Amplifier Circuit 1

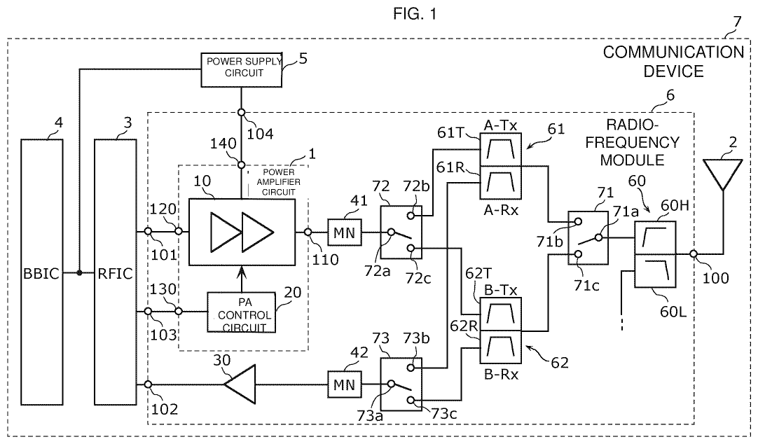

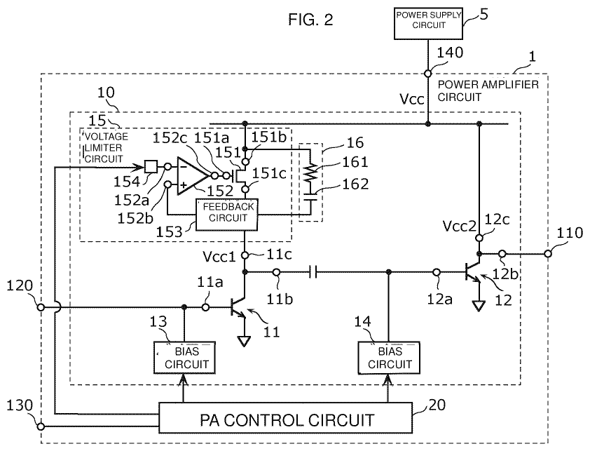

The circuit configurations of a communication device 7, a radio-frequency module 6, and a power amplifier circuit 1 according to a first exemplary embodiment will be described below with reference to FIGS. 1 and 2. FIG. 1 is a circuit diagram of the radio-frequency module 6 and the communication device 7 according to the first exemplary embodiment. FIG. 2 is a circuit diagram of the power amplifier circuit 1 according to the first exemplary embodiment.

### 1.1.1 Circuit Configuration of Communication Device 7

The circuit configuration of the communication device 7 will first be described below. As illustrated in FIG. 1, the communication device 7 includes an antenna 2, an RFIC (Radio Frequency Integrated Circuit) 3, a BBIC (Baseband Integrated Circuit) 4, a power supply circuit 5, and a radio-frequency module 6.

The antenna 2 is connected to an antenna connection terminal 100 of the radio-frequency module 6 and transmits a radio-frequency signal output from the radio-frequency module 6. The antenna 2 also receives a radio-frequency signal from an external source and outputs it to the radio-frequency module 6.

The RFIC 3 is an example of a signal processing circuit that processes a radio-frequency signal. The RFIC 3 will be explained below more specifically. The RFIC 3 performs signal processing, such as down-conversion, on a radio-frequency reception signal, which is received via a receive path of the radio-frequency module 6, and outputs the resulting reception signal to the BBIC 4. The RFIC 3 also performs signal processing, such as up-conversion, on a transmission signal output from the BBIC 4 and outputs the resulting radio-frequency transmission signal to the transmit path of the radio-frequency module 6.

The BBIC 4 is a baseband signal processing circuit that performs signal processing by using an intermediate frequency band, which is lower than a radio-frequency signal transferred by the radio-frequency module 6. Examples of signals to be processed by the BBIC 4 are image signals for displaying images and/or audio signals for performing communication via a speaker.

The power supply circuit 5 supplies a power supply voltage to the power amplifier circuit 1. The specific configuration of the power supply circuit 5 will be discussed later.

The radio-frequency module 6 transfers a radio-frequency signal between the antenna 2 and the RFIC 3. The specific configuration of the radio-frequency module 6 will be discussed later.

The circuit configuration of the communication device 7 shown in FIG. 1 is an example and does not restrict the configuration of the communication device 7. In one example, the provision of the antenna 2 and/or the BBIC 4 in the communication device 7 may be omitted. In another example, the communication device 7 may include plural antennas.

### 1.1.2 Circuit Configuration of Radio-Frequency Module 6

The circuit configuration of the radio-frequency module 6 will now be described below. As illustrated in FIG. 1, the radio-frequency module 6 includes a power amplifier circuit 1, a low-noise amplifier (LNA) 30, matching circuits 41 and 42, a diplexer 60, duplexers 61 and 62, and switches 71, 72, and 73. The radio-frequency module 6 also includes an antenna connection terminal 100, an external input terminal 101, an external output terminal 102, a control terminal 103, and an external power supply terminal 104.

The antenna connection terminal 100 is connected inside the radio-frequency module 6 to the switch 71 via the diplexer 60 and is connected outside the radio-frequency module 6 to the antenna 2. Transmission signals of band A and band B amplified by the power amplifier circuit 1 are output to the antenna 2 via the antenna connection terminal 100. Reception signals of band A and band B received by the antenna 2 are input into the radio-frequency module 6 via the antenna connection terminal 100. Band A and band B will be explained later.

The external input terminal 101 is a terminal for receiving transmission signals of band A and band B from the outside of the radio-frequency module 6. The external input terminal 101 is connected outside the radio-frequency module 6 to the RFIC 3 and is connected inside the radio-frequency module 6 to the power amplifier circuit 1. With this configuration, transmission signals of band A and band B received from the RFIC 3 via the external input terminal 101 are supplied to the power amplifier circuit 1.

The external output terminal 102 is a terminal for outputting reception signals of band A and band B to the outside of the radio-frequency module 6. The external output terminal 102 is connected outside the radio-frequency module 6 to the RFIC 3 and is connected inside the radio-frequency module 6 to the low-noise amplifier 30. With this configuration, reception signals of band A and band B amplified by the low-noise amplifier 30 are output to the RFIC 3 via the external output terminal 102.

The control terminal 103 is a terminal for transferring a control signal. That is, the control terminal 103 is a terminal for receiving a control signal from the outside of the radio-frequency module 6 and/or a terminal for supplying a control signal to the outside of the radio-frequency module 6. A control signal is a signal for controlling an electronic circuit included in the radio-frequency module 6. More specifically, a control signal is a digital signal for controlling a power amplifier 10, for example.

The external power supply terminal 104 is a terminal for receiving a power supply voltage from the power supply circuit 5. The external power supply terminal 104 is connected outside the radio-frequency module 6 to the power supply circuit 5 and is connected inside the radio-frequency module 6 to the power amplifier circuit 1. With this configuration, a power supply voltage received from the power supply circuit 5 via the external power supply terminal 104 is supplied to the power amplifier circuit 1.

The power amplifier circuit 1 can amplify transmission signals of band A and band B. The specific configuration of the power amplifier circuit 1 will be discussed later.

The low-noise amplifier 30 can amplify reception signals of band A and band B.

The matching circuit 41 is connected between the power amplifier circuit 1 and the switch 72. The matching circuit 41 provides impedance matching between the output impedance of the power amplifier circuit 1 and the input impedance of transmit filters 61T and 62T. The matching circuit 41 is constituted by at least one of an inductor and a capacitor, for example.

The matching circuit 42 is connected between the low-noise amplifier 30 and the switch 73. The matching circuit 42 provides impedance matching between the input impedance of the low-noise amplifier 30 and the output impedance of receive filters 61R and 62R. The matching circuit 42 is constituted by at least one of an inductor and a capacitor, for example.

The diplexer 60 includes a high pass filter 60H and a low pass filter 60L. One terminal of the high pass filter 60H and one terminal of the low pass filter 60L are connected to the antenna connection terminal 100. The other terminal of the high pass filter 60H is connected to a terminal 71a of the switch 71. The high pass filter 60H is a filter having a pass band including a first frequency band group containing band A and band B. The low pass filter 60L is a filter having a pass band including a second frequency band group, which is lower than the first frequency band group.

The duplexer 61 has a pass band including band A. The duplexer 61 includes the transmit filter 61T and the receive filter 61R and enables frequency division duplex (FDD) in band A.

The transmit filter 61T (A-Tx) is connected between the power amplifier circuit 1 and the antenna connection terminal 100. More specifically, one end of the transmit filter 61T is connected to the power amplifier circuit 1 via the switch 72 and the matching circuit 41, while the other end of the transmit filter 61T is connected to the antenna connection terminal 100 via the switch 71 and the high pass filter 60H. The transmit filter 61T has a pass band including the uplink operating band of band A. The transmit filter 61T can thus allow, among transmission signals amplified by the power amplifier circuit 1, a transmission signal of band A to pass therethrough.

The receive filter 61R (A-Rx) is connected between the low-noise amplifier 30 and the antenna connection terminal 100. More specifically, one end of the receive filter 61R is connected to the antenna connection terminal 100 via the switch 71 and the high pass filter 60H, while the other end of the receive filter 61R is connected to the low-noise amplifier 30 via the switch 73 and the matching circuit 42. The receive filter 61R has a pass band including the downlink operating band of band A. The receive filter 61R can thus allow, among reception signals received by the antenna 2, a reception signal of band A to pass therethrough.

The duplexer 62 has a pass band including band B. The duplexer 62 includes the transmit filter 62T and the receive filter 62R and enables FDD in band B.

The transmit filter 62T (B-Tx) is connected between the power amplifier circuit 1 and the antenna connection terminal 100. More specifically, one end of the transmit filter 62T is connected to the power amplifier circuit 1 via the switch 72 and the matching circuit 41, while the other end of the transmit filter 62T is connected to the antenna connection terminal 100 via the switch 71 and the high pass filter 60H. The transmit filter 62T has a pass band including the uplink operating band of band B. The transmit filter 62T can thus allow, among transmission signals amplified by the power amplifier circuit 1, a transmission signal of band B to pass therethrough.

The receive filter 62R (B-Rx) is connected between the low-noise amplifier 30 and the antenna connection terminal 100. More specifically, one end of the receive filter 62R is connected to the antenna connection terminal 100 via the switch 71 and the high pass filter 60H, while the other end of the receive filter 62R is connected to the low-noise amplifier 30 via the switch 73 and the matching circuit 42. The receive filter 62R has a pass band including the downlink operating band of band B. The receive filter 62R can thus allow, among reception signals received by the antenna 2, a reception signal of band B to pass therethrough.

Band A and band B are frequency bands used for a communication system to be constructed using a radio access technology (RAT). Band A and band B are predefined by a standardizing body (such as 3GPP (registered trademark) (3rd Generation Partnership Project) and IEEE (Institute of Electrical and Electronics Engineers)). Examples of the communication system are a 5GNR system, an LTE system, and a WLAN (Wireless Local Area Network) system.

The switch 71 is connected between the antenna connection terminal 100 and the duplexers 61 and 62. The switch 71 has terminals 71a, 71b, and 71c. The terminal 71a is connected to the antenna connection terminal 100 via the high pass filter 60H of the diplexer 60. The terminal 71b is connected to the duplexer 61. The terminal 71c is connected to the duplexer 62.

With this connection configuration, the switch 71 can connect the terminal 71a to one of the terminals 71b and 71c based on a control signal from the RFIC 3, for example. That is, the switch 71 can selectively connect the antenna connection terminal 100 to one of the duplexers 61 and 62. The switch 71 is constituted by an SPDT (Single-Pole Double-Throw) switch circuit, for example.

The switch 72 is connected between the transmit filters 61T and 62T and the power amplifier circuit 1. The switch 72 has terminals 72a, 72b, and 72c. The terminal 72a is connected to an external output terminal 110 of the power amplifier circuit 1 via the matching circuit 41. The terminal 72b is connected to the transmit filter 61T. The terminal 72c is connected to the transmit filter 62T.

With this connection configuration, the switch 72 can connect the terminal 72a to one of the terminals 72b and 72c, based on a control signal from the RFIC 3, for example. That is, the switch 72 can selectively connect the power amplifier circuit 1 to one of the transmit filters 61T and 62T. The switch 72 is constituted by an SPDT switch circuit, for example.

The switch 73 is connected between the receive filters 61R and 62R and the low-noise amplifier 30. The switch 73 has terminals 73a, 73b, and 73c. The terminal 73a is connected to the low-noise amplifier 30 via the matching circuit 42. The terminal 73b is connected to the receive filter 61R. The terminal 73c is connected to the receive filter 62R.

With this connection configuration, the switch 73 can connect the terminal 73a to one of the terminals 73b and 73c, based on a control signal from the RFIC 3, for example. That is, the switch 73 can selectively connect the low-noise amplifier 30 to one of the receive filters 61R and 62R. The switch 73 is constituted by an SPDT switch circuit, for example.

The radio-frequency module 6 shown in FIG. 1 is an example and does not restrict the configuration of the radio-frequency module 6. In one example, the provision of the matching circuits 41 and 42 in the radio-frequency module 6 may be omitted. In addition to or instead of the matching circuits 41 and 42, the radio-frequency module 6 may include a different matching circuit. In this case, the different matching circuit is disposed in at least one of the transmit path, receive path, and transmit/receive path.

In another example, the provision of the diplexer 60 in the radio-frequency module 6 may be omitted. In another example, the provision of the duplexer 62 and the switches 71 through 73 in the radio-frequency module 6 may be omitted. Additionally, the provision of the receive path and the low-noise amplifier 30 and the receive filter 61R in the radio-frequency module 6 may be omitted. In another example, the radio-frequency module 6 may include a filter and a power amplifier circuit supporting band C, which is different from band A and band B.

### 1.1.3 Circuit Configuration of Power Amplifier Circuit 1

The circuit configuration of the power amplifier circuit 1 will now be described below. As illustrated in FIGS. 1 and 2, the power amplifier circuit 1 includes a power amplifier 10 and a PA control circuit 20. The power amplifier circuit 1 also includes an external output terminal 110, an external input terminal 120, a control terminal 130, and an external power supply terminal 140.

The external output terminal 110 is a terminal for supplying transmission signals of band A and band B amplified by the power amplifier circuit 1 to the outside of the power amplifier circuit 1. As illustrated in FIG. 2, the external output terminal 110 is connected inside the power amplifier circuit 1 to an output terminal 12b of an amplifying element 12. As illustrated in FIG. 1, the external output terminal 110 is connected outside the power amplifier circuit 1 to the switch 72 via the matching circuit 41. With this configuration, transmission signals supplied via the external output terminal 110 are transferred to the antenna connection terminal 100 via the transmit filters 61T and 62T.

The external input terminal 120 is a terminal for receiving transmission signals of band A and band B from the outside of the power amplifier circuit 1. As illustrated in FIG. 1, the external input terminal 120 is connected outside the power amplifier circuit 1 to the RFIC 3 via the external input terminal 101. As illustrated in FIG. 2, the external input terminal 120 is connected inside the power amplifier circuit 1 to an input terminal 11a of an amplifying element 11. With this configuration, transmission signals of band A and band B received from the RFIC 3 via the external input terminal 120 are supplied to the amplifying element 11 of the power amplifier 10. The external input terminal 120 may be integrated with the external input terminal 101.

The control terminal 130 is a terminal for transferring a control signal. That is, the control terminal 130 is a terminal for receiving a control signal from the outside of the power amplifier circuit 1 and/or a terminal for supplying a control signal to the outside of the power amplifier circuit 1. As shown in FIG. 1, the control terminal 130 is connected outside the power amplifier circuit 1 to the RFIC 3 via the control terminal 103 and is connected inside the power amplifier circuit 1 to the PA control circuit 20. The control terminal 130 may be integrated with the control terminal 103.

The external power supply terminal 140 is a terminal for receiving from the power supply circuit 5 a power supply voltage Vcc to be supplied to the power amplifier 10. As illustrated in FIG. 1, the external power supply terminal 140 is connected outside the power amplifier circuit 1 to the power supply circuit 5 via the external power supply terminal 104. As illustrated in FIG. 2, the external power supply terminal 140 is connected inside the power amplifier circuit 1 to a power supply terminal 11c of the amplifying element 11 and a power supply terminal 12c of the amplifying element 12. More specifically, the external power supply terminal 140 is connected to the power supply terminal 11c of the amplifying element 11 via a voltage limiter circuit 15. An RC series circuit 16 is connected in parallel with the voltage limiter circuit 15. The external power supply terminal 140 is connected to the power supply terminal 12c of the amplifying element 12 without having the voltage limiter circuit 15 interposed therebetween. With this configuration, the power supply voltage Vcc received from the power supply circuit 5 via the external power supply terminal 140 is supplied to the power amplifier 10. The external power supply terminal 140 may be integrated with the external power supply terminal 104.

In the first exemplary embodiment, the power amplifier circuit 1 includes the single external power supply terminal 140, and the radio-frequency module 6 includes the single external power supply terminal 104. “Single” means “only one”. With this configuration, the power supply voltage received by the single external power supply terminal 140 is supplied to each of the amplifying elements 11 and 12 via power supply wiring provided inside the power amplifier circuit 1. That is, the power supply wiring connects the single external power supply terminal 140 to each of the power supply terminals 11c and 12c and has a branch point at a mid-position of a path from the external power supply terminal 140 to the power supply terminals 11c and 12c.

The expression “including the single external power supply terminal” means that “only one” external power supply terminal receives a power supply voltage to be supplied to each of the amplifying elements 11 and 12. However, this expression does not mean that the power amplifier circuit 1 or the radio-frequency module 6 does not have a power supply terminal for supplying a voltage (or power) to another amplifying element or a circuit element. That is, the power amplifier circuit 1 or the radio-frequency module 6 may have an external power supply terminal that receives a voltage (or power) to be supplied to the PA control circuit 20, for example.

The power amplifier 10 amplifies transmission signals of band A and band B. The power amplifier 10 has a multistage structure of amplifying elements. The specific configuration of the power amplifier 10 will be discussed later.

The PA control circuit 20 is an example of a control circuit that controls the power amplifier 10. More specifically, the PA control circuit 20 controls a bias to be supplied to the amplifying elements 11 and 12 and the operation of the voltage limiter circuit 15. For example, the PA control circuit 20 outputs a control signal to each of bias circuits 13 and 14 and the voltage limiter circuit 15.

### 1.1.4 Circuit Configuration of Power Amplifier 10

The specific circuit configuration of the power amplifier 10 will be discussed below. As illustrated in FIG. 2, the power amplifier 10 includes the amplifying elements 11 and 12, bias circuits 13 and 14, voltage limiter circuit 15, and RC series circuit 16.

The amplifying element 11 is an example of a first amplifying element and has an input terminal 11a, an output terminal 11b, and a power supply terminal 11c. The input terminal 11a is an example of a first input terminal and is connected to the external input terminal 120. The input terminal 11a is also connected to the bias circuit 13. The output terminal 11b is an example of a first output terminal and is connected to an input terminal 12a of the amplifying element 12. The power supply terminal 11c is an example of a first power supply terminal and is connected to the external power supply terminal 140 via the voltage limiter circuit 15.

A power supply voltage Vcc1 is supplied to the power supply terminal 11c via the voltage limiter circuit 15. The amplifying element 11 amplifies a transmission signal input via the input terminal 11a by using the power supply voltage Vcc1 and outputs the amplified transmission signal via the output terminal 11b. The amplifying element 11 forms the input stage (drive stage) of a multistage amplifier circuit.

For example, the amplifying element 11 includes a bipolar junction transistor (BJT), such as a heterojunction bipolar transistor (HBT). The base of the BJT is connected to the input terminal 11a, and the collector of the BJT is connected to the output terminal 11b and the power supply terminal 11c. The emitter of the BJT is grounded.

The amplifying element 11 may alternatively be a field effect transistor (FET), such as a MOSFET (Metal Oxide Semiconductor Field Effect Transistor). In this case, the gate of the FET is connected to the input terminal 11a, and the drain of the FET is connected to the output terminal 11b and the power supply terminal 11c. The source of the FET is grounded.

The amplifying element 12 is an example of a second amplifying element and has an input terminal 12a, an output terminal 12b, and a power supply terminal 12c. The input terminal 12a is an example of a second input terminal and is connected to the output terminal 11b of the amplifying element 11. The input terminal 12a is also connected to the bias circuit 14. The output terminal 12b is an example of a second output terminal and is connected to the external output terminal 110. The power supply terminal 12c is an example of a second power supply terminal and is connected to the external power supply terminal 140 without having the voltage limiter circuit 15 interposed therebetween. A DC-cut capacitor is connected in series with between the input terminal 12a and the output terminal 11b.

The power supply voltage Vcc is supplied to the power supply terminal 12c as a power supply voltage Vcc2. That is, unlike the amplifying element 11, the power supply voltage Vcc is directly supplied to the amplifying element 12 without having the voltage limiter circuit 15 interposed therebetween. The amplifying element 12 amplifies a transmission signal which is amplified by the amplifying element 11 and which is input via the input terminal 12a and outputs the amplified transmission signal via the output terminal 12b. The amplifying element 12 forms the output stage (power stage) of the multistage amplifier circuit.

For example, the amplifying element 12 includes a bipolar junction transistor (BJT), such as an HBT. The base of the BJT is connected to the input terminal 12a, and the collector of the BJT is connected to the output terminal 12b and the power supply terminal 12c. The emitter of the BJT is grounded.

The amplifying element 12 may alternatively be a field effect transistor (FET), such as a MOSFET. In this case, the gate of the FET is connected to the input terminal 12a, and the drain of the FET is connected to the output terminal 12b and the power supply terminal 12c. The source of the FET is grounded.

The power amplifier 10 may include three or more amplifying elements connected to each other in multiple stages. In this case, the amplifying element 11 to which the voltage limiter circuit 15 is connected is the amplifying element of the first stage. The power supply voltage Vcc is directly supplied to the power supply terminals of the amplifying elements other than that of the first stage.

The bias circuit 13 supplies a bias current or a bias voltage to the amplifying element 11. In the first exemplary embodiment, the bias circuit 13 supplies a DC bias current to the input terminal 11a of the amplifying element 11.

The bias circuit 14 supplies a bias current or a bias voltage to the amplifying element 12. In the first exemplary embodiment, the bias circuit 14 supplies a DC bias current to the input terminal 12a of the amplifying element 12.

The voltage limiter circuit 15 is an example of a first circuit. The voltage limiter circuit 15 restricts the power supply voltage Vcc to a predetermined range and outputs the restricted power supply voltage Vcc. More specifically, the voltage limiter circuit 15 restricts the upper limit value of the power supply voltage Vcc. The upper limit value is lower than the maximum value of the voltage level of the power supply voltage Vcc.

When the power supply voltage Vcc exceeds the set upper limit value, the voltage limiter circuit 15 outputs the voltage of the upper limit value. When the power supply voltage Vcc does not exceed the set upper limit value, the voltage limiter circuit 15 outputs the power supply voltage Vcc without restricting it. It is now assumed that the upper limit value is 3 V, for example. If the power supply voltage Vcc is 5 V, the voltage limiter circuit 15 outputs a voltage of 3 V, which is the upper limit value. If the power supply voltage Vcc is 2 V, the voltage limiter circuit 15 outputs a voltage of 2 V. The voltage limiter circuit 15 is also called a low dropout circuit (LDO circuit) or an LDO linear regulator.

As illustrated in FIG. 2, the voltage limiter circuit 15 includes a transistor 151, an amplifying element 152, a feedback circuit 153, and a control terminal 154.

The transistor 151 is connected between the external power supply terminal 140 and the power supply terminal 11c of the amplifying element 11. More specifically, the transistor 151 has a control terminal 151a, an input terminal 151b, and an output terminal 151c. The control terminal 151a is connected to an output terminal 152c of the amplifying element 152. The input terminal 151b is connected to the external power supply terminal 140. The output terminal 151c is connected to the power supply terminal 11c of the amplifying element 11.

The transistor 151, which is an output driver of the voltage limiter circuit 15, converts a voltage Vcc applied to the input terminal 151b into a desired power supply voltage Vcc1 and outputs it. More specifically, the transistor 151 outputs the power supply voltage Vcc1 which does not exceed the set upper limit value.

The transistor 151 is a p-type MOSFET, for example. The control terminal 151a is the gate, the input terminal 151b is the source, and the output terminal 151c is the drain. The transistor 151 may alternatively be an n-type MOSFET or an FET other than a MOSFET. The transistor 151 may be a bipolar junction transistor (BJT).

The amplifying element 152 is an example of a third amplifying element and has input terminals 152a and 152b and an output terminal 152c. The amplifying element 152 is an operational amplifier and is also called an error amplifier. The input terminal 152a is an inverting input terminal and is connected to the control terminal 154. The input terminal 152b is an example of a third input terminal. The input terminal 152b is a non-inverting input terminal and is connected to the feedback circuit 153. The output terminal 152c is an example of a third output terminal and is connected to the control terminal 151a of the transistor 151.

The amplifying element 152 outputs a voltage corresponding to a voltage difference between the two input terminals 152a and 152b to the output terminal 152c. With this operation, the amplifying element 152 can control the ON-resistance of the transistor 151 so as to regulate the power supply voltage Vcc1 output from the output terminal 151c of the transistor 151 to be a desired value.

The feedback circuit 153 is connected between the power supply terminal 11c of the amplifying element 11 and the input terminal 152b of the amplifying element 152. More specifically, the feedback circuit 153 is connected between the input terminal 152b and a path connecting the output terminal 151c of the transistor 151 and the power supply terminal 11c.

The feedback circuit 153 includes two resistors connected in series with each other (not shown), for example. One end of each of the two resistors is connected to the path connecting the output terminal 151c of the transistor 151 and the power supply terminal 11c of the amplifying element 11. The other ends of the two resistors are grounded. The connecting portion of the two resistors is connected to the input terminal 152b. With this configuration, the feedback circuit 153 can input a value corresponding to the power supply voltage Vcc1 output from the output terminal 151c of the transistor 151 into the input terminal 152b of the amplifying element 152.

The control terminal 154 is a terminal for receiving a control signal input from the PA control circuit 20. The control signal can control ON/OFF of the operation of the voltage limiter circuit 15. The control signal can also set the upper limit value of the power supply voltage Vcc1 to be output from the voltage limiter circuit 15. The upper limit value may be variable.

With the above-described configuration, the power supply voltage Vcc1 whose upper limit value is regulated is supplied to the power supply terminal 11c of the amplifying element 11. That is, when the power supply voltage Vcc exceeds the upper limit value, the level of the power supply voltage Vcc1 is restricted to the voltage level of the upper limit value. When the power supply voltage Vcc does not exceed the upper limit value, the level of the power supply voltage Vcc1 becomes equal to the level of the power supply voltage Vcc.

The voltage limiter circuit 15 shown in FIG. 2 is an example and does not restrict the configuration of the voltage limiter circuit 15. The voltage limiter circuit 15 may be any type of circuit if it can restrict the power supply voltage Vcc to a predetermined range and output the restricted power supply voltage Vcc. The voltage limiter circuit 15 may restrict the lower limit value as well as the upper limit value.

The RC series circuit 16 is an example of a first RC series circuit and is connected in parallel with the voltage limiter circuit 15. The RC series circuit 16 is also called an RC snubber circuit.

The RC series circuit 16 includes a resistor 161 and a capacitor 162. The resistor 161 and the capacitor 162 are connected in series with each other. For example, the resistor 161 is connected at one end to a path connecting the external power supply terminal 140 and the input terminal 151b of the transistor 151 and is connected at the other end to one end of the capacitor 162. The other end of the capacitor 162 is connected to the path connecting the output terminal 151c of the transistor 151 and the power supply terminal 11c of the amplifying element 11. The path and the element to which the resistor 161 are connected and those to which the capacitor 162 is connected may be swapped.

### 1.2 Explanation of Supply Modes of Power Supply Voltage

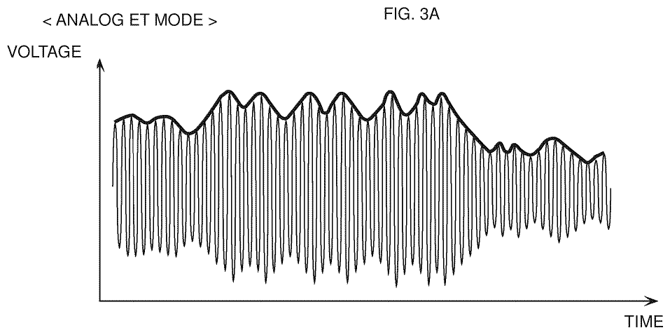

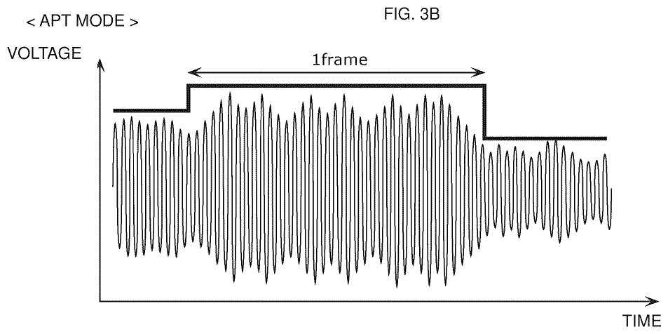

Supply modes of the power supply voltage Vcc supplied by the power supply circuit 5 will be explained below with reference to FIGS. 3A and 3B. FIG. 3A is a graph illustrating an example of the transition of a power supply voltage in an analog ET mode. FIG. 3B is a graph illustrating an example of the transition of a power supply voltage in an APT mode. In FIGS. 3A and 3B, the horizontal axis indicates the time, and the vertical axis indicates the voltage. The thick solid line represents the power supply voltage, while the thin solid line (waveform) represents a modulated signal.

In the analog ET mode, as shown in FIG. 3A, the power supply voltage is continuously varied so as to track the envelope of the modulated signal. In the analog ET mode, the power supply voltage is determined based on an envelope signal. In the analog ET mode, if the envelope of a modulated signal fluctuates at high speed, it is difficult for a power supply voltage to track the envelope of the modulated signal.

The envelope signal is a signal indicating the envelope of a modulated signal. The envelope value is represented by a square root of (i²+Q²), for example. (i, Q) is a constellation point. The constellation point is a point of a signal modulated by digital modulation on a constellation diagram. (i, Q) is determined by the BBIC 4 based on transmission information, for example.

In the APT mode, as shown in FIG. 3B, the power supply voltage is varied to multiple discrete voltage levels in units of frames. As a result, the power supply voltage signal forms a rectangular wave. In the APT mode, the voltage level may be varied in a unit smaller than a frame (subframe, for example).

A frame is a unit which forms a radio-frequency signal (modulated signal). For example, 5GNR (5th Generation New Radio) and LTE (Long Term Evolution) define that a frame includes ten subframes, each subframe includes plural slots, and each slot is constituted by plural symbols. The subframe length is 1 ms, and the frame length is 10 ms.

For example, the power supply circuit 5 presets a power supply voltage of multiple discrete voltage levels and selects one of the preset voltage levels by using a switch (not shown) and outputs the selected voltage level. The power supply circuit 5 can thus implement high-speed switching using the switch to change the level of the power supply voltage to be supplied to the power amplifier circuit 1. Instead of presetting multiple voltage levels and selecting and outputting a voltage level by using the switch, the power supply circuit 5 may obtain multiple voltage levels in a different manner. For example, when necessary, the power supply circuit 5 may generate a voltage level, which is a voltage level selected from multiple discrete voltage levels, and output the generated voltage level.

### 1.3 Operation of Communication Device 7

The operation of the communication device 7 including the power amplifier circuit 1 according to the first exemplary embodiment will now be described below.

It is now assumed that the communication device 7 according to the first exemplary embodiment is used as user equipment (UE) in a cellular network. In this case, the communication device 7 controls output power in response to a transfer power control command (TPC_cmd) sent from a base station (BS) to the communication device 7, based on 3GPP inner loop power control. 4G (4th generation) and 5G (5th generation) demand a high precision of output power from a UE (mobile terminal). In one example, if a transfer power control command of a mode TPC_cmd(+1) is sent from a base station, a UE is required to adjust output power to a range of +0.5 dB to +1.5 dB in response to the command value. In another example, if a transfer power control command of a mode TPC_cmd(0) is sent from a base station, a UE is required to adjust output power to a range of −0.5 dB to +0.5 dB in response to the command value. In another example, if a transfer power control command of a mode TPC_cmd(−1) is sent from a base station, a UE is required to adjust output power to a range of −1.5 dB to −0.5 dB in response to the command value.

However, in a power amplifier circuit whose gain deviation in response to variations of the power supply voltage Vcc is large, output power of a radio-frequency output signal (transmission signal) may deviate from the output power range responding to a transfer power control command and fail to satisfy the output power standards (power range), especially in a high gain region. This may degrade the quality of the radio-frequency output signal.

In view of this background, when the power amplifier circuit 1 of the first exemplary embodiment operates in the APT mode, it is able to regulate a gain deviation caused by a change in the output power. More specifically, the voltage limiter circuit 15 restricts the level of the power supply voltage to be supplied to the amplifying element 11 so as to regulate the gain deviation. This can reduce the quality degradation of a radio-frequency signal output from the power amplifier circuit 1.

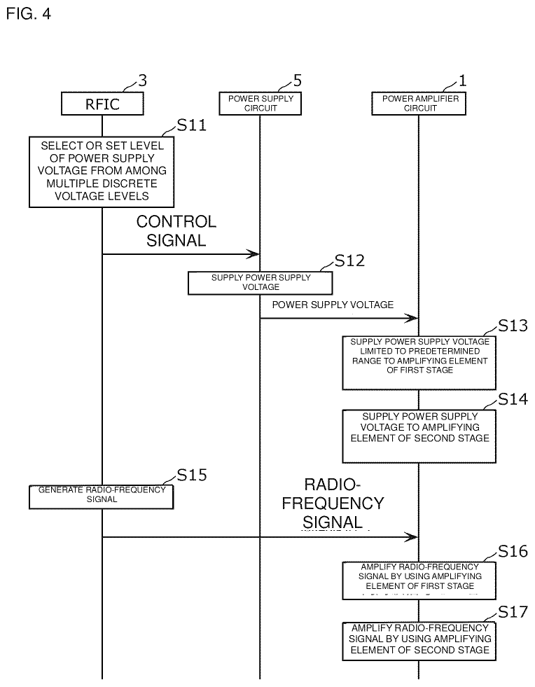

The specific operation of the communication device 7 according to the first exemplary embodiment will now be described below with reference to FIG. 4. FIG. 4 is a sequence diagram illustrating the operation of the communication device 7 according to the first exemplary embodiment.

From among multiple discrete voltage levels, the RFIC 3 selects or sets the level of a power supply voltage to be used in the power amplifier circuit 1 (S11). For example, the RFIC 3 selects or sets the level of the power supply voltage Vcc based on average output power of a radio-frequency signal. A control signal indicating the voltage level set or selected in this manner is output to the power supply circuit 5.

The power supply circuit 5 supplies a power supply voltage of the selected or set voltage level to the power amplifier circuit 1 in accordance with a control signal from the RFIC 3 (S12). For example, the power supply circuit 5 generates a reference voltage level based on an input voltage output from an external power supply and generates multiple discrete voltage levels from the reference voltage level. Then, by controlling a switch in accordance with the control signal from the RFIC 3, the power supply circuit 5 selects one of the generated multiple discrete voltage levels and outputs a power supply voltage of the selected voltage level to the power amplifier circuit 1.

The power amplifier circuit 1 supplies the power supply voltage Vcc1 restricted to a predetermined range to the amplifying element 11 of the first stage (S13). More specifically, the voltage limiter circuit 15 to which the RC series circuit 16 is parallel-connected restricts the power supply voltage Vcc received from the power supply circuit 5 to the predetermined range and supplies the restricted power supply voltage Vcc as the power supply voltage Vcc1. For example, if the power supply voltage Vcc exceeds the upper limit value, the power supply voltage Vcc1 having a voltage level of the upper limit value is supplied to the power supply terminal 11c of the amplifying element 11. If the power supply voltage Vcc does not exceed the upper limit value, the power supply voltage Vcc is not restricted to the predetermined range and is supplied to the power supply terminal 11c of the amplifying element 11 as the power supply voltage Vcc1.

The power amplifier circuit 1 does not restrict the power supply voltage Vcc and supplies it to the amplifying element 12 of the second stage as the power supply voltage Vcc2 (S14). In this example, step S13 and step S14 are executed in this order. Alternatively, step S14 may be executed first before step S13, or the two steps may be executed at the same time.

The RFIC 3 generates a radio-frequency signal and outputs it to the power amplifier circuit 1 (S15). The amplifying element 11 amplifies the radio-frequency signal by using the power supply voltage Vcc1 supplied from the voltage limiter circuit 15 (S16). The amplifying element 12 amplifies the radio-frequency signal amplified by the amplifying element 11 by using the power supply voltage Vcc2, which is the power supply voltage Vcc received from the power supply circuit 5 (S17).

### 1.4 Exemplary Advantages of Voltage Limiter Circuit 15 and RC Series Circuit 16

Exemplary advantages of the voltage limiter circuit 15 and the RC series circuit 16 according to the first exemplary embodiment will now be described below.

### 1.4.1 Exemplary Advantages of Voltage Limiter Circuit 15

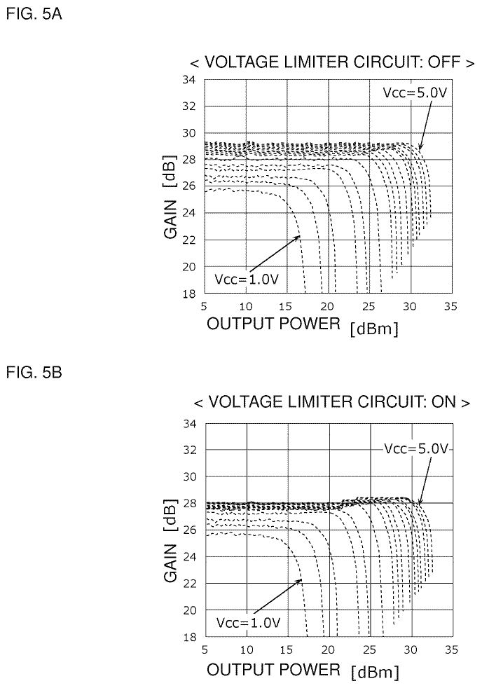

Exemplary advantages of the voltage limiter circuit 15 will first be discussed below with reference to FIGS. 5A and 5B. FIG. 5A is a graph illustrating the gain when the voltage limiter circuit 15 is in the OFF state. FIG. 5B is a graph illustrating the gain when the voltage limiter circuit 15 is in the ON state. In each of FIGS. 5A and 5B, the horizontal axis indicates output power of the power amplifier circuit 1, and the vertical axis indicates the gain of the power amplifier circuit 1.

The voltage limiter circuit 15 can enter the OFF state by controlling the level of a voltage supplied from the control terminal 154. The state in which the voltage limiter circuit 15 is OFF means that the power supply voltage Vcc input into the input terminal 151b of the transistor 151 is not restricted to the predetermined range and is supplied to the power supply terminal 11c of the amplifying element 11. That is, the state in which the voltage limiter circuit 15 is OFF is the same as the state in which the voltage limiter circuit 15 is not provided and the external power supply terminal 140 and the power supply terminal 11c of the amplifying element 11 are directly connected to each other. The state in which the voltage limiter circuit 15 is OFF is the same as the state in which the upper limit value greater than or equal to the maximum value (5.0 V, for example) of the power supply voltage Vcc may also be set.

As stated above, the power supply voltage Vcc, which is discretely variable to multiple voltage levels, is supplied from the power supply circuit 5 to the power amplifier circuit 1 of the first exemplary embodiment. If this power supply voltage Vcc is not restricted to the predetermined range and is supplied to both of the amplifying elements 11 and 12, the gain deviation unfavorably increases.

The gain deviation will now be explained below. In FIG. 5A, a change in the gain (gain characteristics) in the case of supplying the power supply voltage Vcc (=Vcc1=Vcc2) of multiple discrete voltage levels is indicated by the broken line in accordance with the individual levels of the power supply voltage Vcc. As the power supply voltage Vcc becomes higher, the gain becomes larger and output power that can be output without decreasing the level of gain becomes higher. The difference between the gain obtained when the level of the power supply voltage V_{ET} is the minimum value (1.0 V in this example) and the gain obtained when the level of the power supply voltage V_{ET} is the maximum value (5.0 V in this example) is the gain deviation.

As discussed above, in the APT mode, the power supply voltage Vcc is determined based on average output of a radio-frequency signal. In response to discrete variations of the power supply voltage Vcc in the APT mode, the gain of the power amplifier circuit 1 is also discretely varied. A high gain deviation causes a large gain difference responding to a change in output power, thereby degrading the quality of a radio-frequency output signal.

To address this issue, in the first exemplary embodiment, the voltage limiter circuit 15 is operated in the APT mode. That is, as a result of restricting the upper limit value of the power supply voltage Vcc supplied to the external power supply terminal 140, the power supply voltage Vcc1 having a voltage level lower than or equal to the upper limit value is supplied to the power supply terminal 11c of the amplifying element 11.

This decreases the gain deviation. This is because, among the gain characteristics (indicated by the broken lines in the graph) corresponding to the individual voltage levels, the gain represented by the gain characteristics corresponding to the power supply voltage Vcc exceeding the upper limit value becomes smaller, as shown in FIG. 5B. Because of a smaller gain deviation, output power of a radio-frequency output signal (transmission signal) is less likely to deviate from a output power range based on a transfer power control command and to fail to satisfy the output power standards (power range). This can reduce the quality degradation of the radio-frequency output signal.

In FIG. 5B, the upper limit value is set to 3.0 V. It is now assumed that the power supply voltage Vcc is 5.0 V, for example. In this case, within a range of output power (5 dBm to 30 dBm, for example) in which the gain variations are small, the gain is about 29 dB in the example in FIG. 5A. Within the same range of output power, the gain is about 28 dB in the example in FIG. 5B. This shows that, when the voltage limiter circuit 15 is in the ON state, the gain deviation becomes smaller by about 1 dB than when the voltage limiter circuit 15 is in the OFF state.

Regarding the influence on the quality of a radio-frequency signal output from the power amplifier circuit 1, the influence caused by variations of the power supply voltage Vcc1 supplied to the amplifying element 11 of the first stage (drive stage) is much greater than that by variations of the power supply voltage Vcc supplied to the amplifying element 12. Hence, as a result of the voltage limiter circuit 15 diminishing the variations of the power supply voltage Vcc1 to be supplied to the power supply terminal 11c of the amplifying element 11 of the first stage, the gain deviation can be efficiently lowered. A smaller gain deviation reduces the quality degradation of a radio-frequency signal.

Meanwhile, the power supply voltage Vcc is not restricted to the predetermined range and is supplied to the power supply terminal 12c of the amplifying element 12 of the second stage (power stage). The operation of the amplifying element 12 of the second stage significantly influences output power. That is, when the power supply voltage Vcc exceeding the upper limit value is supplied to the external power supply terminal 140, the amplifying element 12 amplifies a radio-frequency signal by using this power supply voltage Vcc, thereby achieving high output from the power amplifier circuit 1.

Regardless of the level of the power supply voltage Vcc, the voltage of a fixed value may be supplied to the power supply terminal 11c of the amplifying element 11 of the first stage. The fixed value is a value lower than the maximum value of the voltage level of the power supply voltage Vcc. That is, the predetermined range to which the voltage limiter circuit 15 restricts the power supply voltage Vcc may be a single voltage level (upper limit value=lower limit value). In this case, too, the exemplary advantages obtained by a smaller gain deviation are achieved.

In contrast, only the upper limit value may be set, as in the above-described first exemplary embodiment. In this case, when the power supply voltage Vcc of a voltage level lower than the upper limit value is supplied, it is not changed and is supplied to the power supply terminal 11c of the amplifying element 11. This can reduce a waste of power consumption compared with when the voltage of a fixed value is supplied to the power supply terminal 11c of the amplifying element 11, thereby making it less likely to lower the efficiency.

As described above, the provision of the voltage limiter circuit 15 can efficiently make the gain deviation small, thereby reducing the quality degradation of a radio-frequency signal. Nevertheless, there may be some cases in which only the voltage limiter circuit 15 is unable to sufficiently reduce the quality degradation of a radio-frequency signal. For example, if variations of the power supply voltage Vcc pass the upper limit value of the voltage limiter circuit 15, the gain deviation is increased.

To address this issue, a high-capacitance capacitor may be provided as a bypass capacitor (or a decoupling capacitor). If, however, the power supply voltage Vcc passes the upper limit value of the voltage limiter circuit 15 and then falls, the bypass capacitor needs discharging. Discharging takes time and the bypass capacitor may thus fail to follow a high speed of variations of the power supply voltage Vcc. If the capacitance of the bypass capacitor is reduced, discharging becomes unrequired. Yet, if the power supply voltage Vcc passes the upper limit value of the voltage limiter circuit 15 and then rises, ringing occurs in the power supply voltage Vcc1 output from the voltage limiter circuit 15.

In this manner, there may be a case in which even the provision of a bypass capacitor is unable to control the deterioration of amplification characteristics of the power amplifier circuit 1 and fails to reduce the quality degradation of a radio-frequency output signal. To deal with this issue, in the first exemplary embodiment, the RC series circuit 16 is provided.

### 1.4.2 Exemplary Advantages of RC Series Circuit 16

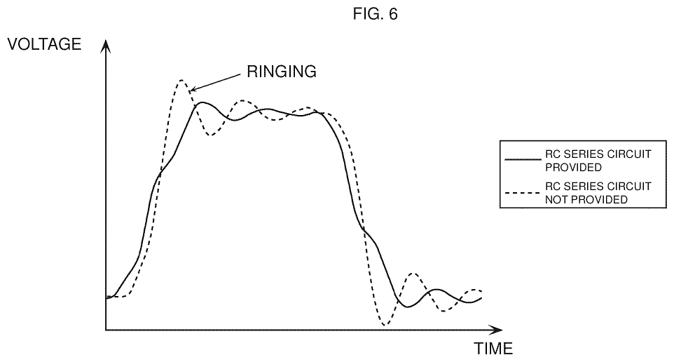

Exemplary advantages of the RC series circuit 16 will now be described below with reference to FIG. 6. FIG. 6 is a graph illustrating an example of variations of the power supply voltage Vcc1 when the RC series circuit 16 is provided and those when the RC series circuit 16 is not provided. In FIG. 6, the horizontal axis indicates time, and vertical axis indicates variations of the power supply voltage Vcc1 supplied to the power supply terminal 11c of the amplifying element 11.

In the APT mode, the power supply voltage Vcc is discretely varied, and when the power supply voltage Vcc is varied, radio-frequency noise called ringing occurs. The broken line in FIG. 6 represents variations of the power supply voltage Vcc1 when the RC series circuit 16 is not provided. The solid line in FIG. 6 represents variations of the power supply voltage Vcc1 when the RC series circuit 16 is provided. As shown in FIG. 6, the provision of the RC series circuit 16 suppresses ringing occurring at a rise of the power supply voltage Vcc1.

An approach to setting the resistance value R_{SNB} of the resistor 161 of the RC series circuit 16 and the capacitance value C_{SNB} of the capacitor 162 of the RC series circuit 16 which are suitable for suppressing the occurrence of ringing will be discussed below.

Ringing can be suppressed by lowering the frequency of variations of the power supply voltage Vcc1. This will be explained by taking an example in which a capacitor is added in parallel with between the input terminal 151b and the output terminal 151c of the transistor 151. The capacitance value of a capacitor to be added is represented by C₁ and the shift ratio of the frequency when the capacitor is added is represented by m. Then, the shift ratio m can be expressed by the following equation (1).

$$\begin{matrix}[ Math . 1 ] & \\ m = \frac{{f}_{R 1}}{{f}_{R 2}} = \frac{\frac{1}{2 π \sqrt{{L}_{p} {C}_{p}}}}{\frac{1}{2 π \sqrt{{L}_{p} ( {C}_{p} + {C}_{1} )}}} & ( 1 )\end{matrix}$$

In equation (1), f_{R1} is the frequency of ringing before the capacitor is added, and f_{R2} is the frequency of ringing after the capacitor is added. In equation (1), L_{P} is the inductance value of a parasitic inductor of the voltage limiter circuit 15. The parasitic inductor is connected in series with the path connecting the external power supply terminal 140 and the input terminal 151b. In equation (1), C_{P} is the capacitance value of a parasitic capacitor of the voltage limiter circuit 15. The parasitic capacitor is connected in parallel with between the input terminal 151b and the output terminal 151c.

Equation (1) is squared and is transformed with respect to C_{P}. Then, the capacitance value C_{P} of the parasitic capacitor can be expressed by the following equation (2).

$$\begin{matrix}[ Math . 2 ] & \\ {C}_{p} = \frac{{C}_{1}}{( {m}^{2} - 1 )} & ( 2 )\end{matrix}$$

Likewise, the inductance value L_{P} of the parasitic inductor can be expressed by the following equation (3).

$$\begin{matrix}[ Math . 3 ] & \\ {L}_{p} = \frac{{m}^{2} - 1}{{( 2 π {f}_{R 1} )}^{2} \times {C}_{1}} & ( 3 )\end{matrix}$$

As a result of adding a capacitor of C₁=100 pF in parallel, for example, and measuring the voltage variations, the capacitance value C_{P} of the parasitic capacitor of the voltage limiter circuit 15 and the inductance value L_{P} of the parasitic inductor of the voltage limiter circuit 15 can be calculated by equations (2) and (3). f_{R1} and f_{R2} can be found from the measurement results of the voltage variations.

To minimize the reflection of a signal from the RC series circuit 16, the following equation (4) is desirably satisfied to implement impedance matching in the RC series circuit 16.

$$\begin{matrix}[ Math . 4 ] & \\ {R}_{S N B} = \sqrt{\frac{{L}_{p}}{{C}_{p}}} & ( 4 )\end{matrix}$$

The capacitance value C_{SNB} of the capacitor 162 of the RC series circuit 16 is set to a range, which is one time to four times greater than the capacitance value C_{P} of the parasitic capacitor, for example. Alternatively, the capacitance value C_{SNB} may be set to a value expressed by the following equation (5).

$$\begin{matrix}[ Math . 5 ] & \\ {C}_{S N B} = \frac{1}{2 π {R}_{S N B} {f}_{R 1}} & ( 5 )\end{matrix}$$

Since L_{P}, C_{P}, and f_{R1} are all found as a result of adding a capacitor of C₁=100 pF in parallel, for example, and measuring the voltage variations, the resistance value R_{SNB} of the resistor 161 and the capacitance value C_{SNB} of the capacitor 162 can be set. With this setting, the RC series circuit 16 suitable for suppressing the occurrence of ringing can be connected in parallel with the voltage limiter circuit 15.

### 1.4.3 Conclusions

As described above, a power amplifier circuit 1 according to the first exemplary embodiment includes an external input terminal 120, an external output terminal 110, a power amplifier 10, and an external power supply terminal 140. The external power supply terminal 140 receives from a power supply circuit 5 a power supply voltage Vcc to be supplied to the power amplifier 10. The power amplifier 10 includes amplifying elements 11 and 12, a voltage limiter circuit 15, and an RC series circuit 16. The amplifying element 11 has an input terminal 11a, an output terminal 11b, and a power supply terminal 11c. The amplifying element 12 has an input terminal 12a, an output terminal 12b, and a power supply terminal 12c. The voltage limiter circuit 15 restricts the power supply voltage Vcc to a predetermined range and outputs the restricted power supply voltage. The RC series circuit 16 is connected in parallel with the voltage limiter circuit 15. The input terminal 11a is connected to the external input terminal 120. The output terminal 11b is connected to the input terminal 12a. The output terminal 12b is connected to the external output terminal 110. The power supply terminal 11c is connected to the external power supply terminal 140 via the voltage limiter circuit 15. The power supply terminal 12c is connected to the external power supply terminal 140.

With this configuration, the power supply voltage Vcc1 restricted by the voltage limiter circuit 15 is supplied to the power supply terminal 11c of the amplifying element 11 of the first stage. This can efficiently lower the gain deviation in the case of supplying the power supply voltage Vcc of multiple discrete voltage levels to the power amplifier 10. A smaller gain deviation reduces the quality degradation of a radio-frequency signal. Additionally, since the RC series circuit 16 is connected in parallel with the voltage limiter circuit 15, ringing occurring in the power supply voltage Vcc1 can be suppressed. In particular, ringing which occurs at a rise of the power supply voltage Vcc1, such as at the start of sending a signal, can be suppressed. The gain of the power amplifier 10 is significantly influenced by the gain characteristics of the amplifying element 11 of the first stage. Hence, as a result of suppressing the occurrence of ringing in the power supply voltage Vcc1 supplied to the amplifying element 11 of the first stage, variations of the power supply voltage Vcc1 in the case of supplying the power supply voltage Vcc of multiple discrete voltage levels can be regulated. Using the power amplifier circuit 1 according to the first exemplary embodiment can thus reduce the quality degradation of a radio-frequency output signal in the case of supplying the power supply voltage Vcc of multiple discrete voltage levels.

Moreover, for example, in the power amplifier circuit 1 according to the first exemplary embodiment, the voltage limiter circuit 15 includes an amplifying element 152, a transistor 151, and a feedback circuit 153. The amplifying element 152 has an input terminal 152b and an output terminal 152c. The transistor 151 has a control terminal 151a connected to the output terminal 152c and is connected between the external power supply terminal 140 and the power supply terminal 11c. The feedback circuit 153 is connected between the power supply terminal 11c and the input terminal 152b.

With this configuration, the power supply voltage Vcc1 restricted by the voltage limiter circuit 15 is supplied to the power supply terminal 11c of the amplifying element 11 of the first stage. This can efficiently lower the gain deviation in the case of supplying the power supply voltage Vcc of multiple discrete voltage levels to the power amplifier 10. Additionally, since the RC series circuit 16 is connected in parallel with the voltage limiter circuit 15, ringing occurring in the power supply voltage Vcc1 can be suppressed. In particular, ringing which occurs at a rise of the power supply voltage Vcc1, such as at the start of sending a signal, can be suppressed. The gain of the power amplifier 10 is significantly influenced by the gain characteristics of the amplifying element 11 of the first stage. Hence, as a result of suppressing the occurrence of ringing in the power supply voltage Vcc1 supplied to the amplifying element 11 of the first stage, variations of the power supply voltage Vcc1 in the case of supplying the power supply voltage Vcc of multiple discrete voltage levels can be regulated. Using the power amplifier circuit 1 according to the first exemplary embodiment can thus reduce the quality degradation of a radio-frequency output signal in the case of supplying the power supply voltage Vcc of multiple discrete voltage levels.

Additionally, for example, the external power supply terminal 140 is a single external power supply terminal.

With this configuration, the power amplifier circuit 1 needs fewer external connection terminals, thereby enhancing the miniaturization of the power amplifier circuit 1. This can also reduce the number of external connection terminals of a radio-frequency module 6 including the power amplifier circuit 1, thereby also enhancing the miniaturization of the radio-frequency module 6.

According to a power amplification method of the first exemplary embodiment, the voltage limiter circuit 15 to which the RC series circuit 16 is parallel-connected restricts a power supply voltage Vcc received from the power supply circuit 5 to a predetermined range and supplies the restricted power supply voltage to the amplifying element 11; the amplifying element 11 amplifies a radio-frequency signal by using the power supply voltage Vcc1 received from the voltage limiter circuit 15; and the amplifying element 12 amplifies the radio-frequency signal amplified by the amplifying element 11 by using the power supply voltage Vcc received from the power supply circuit 5.

With this method, exemplary advantages similar to those implemented by the above-described power amplifier circuit 1 can be obtained. Specifically, exemplary advantages obtained by the power amplification method are as follows. The power supply voltage Vcc1 restricted by the voltage limiter circuit 15 is supplied to the power supply terminal 11c of the amplifying element 11 of the first stage. This can efficiently lower the gain deviation in the case of supplying the power supply voltage Vcc of multiple discrete voltage levels. Additionally, since the RC series circuit 16 is connected in parallel with the voltage limiter circuit 15, ringing occurring in the power supply voltage Vcc1 can be suppressed. In particular, ringing which occurs at a rise of the power supply voltage Vcc1, such as at the start of sending a signal, can be suppressed. The gain of the power amplifier 10 including the amplifying element 11 of the first stage and the amplifying element 12 of the second stage is significantly influenced by the gain characteristics of the amplifying element 11 of the first stage. Hence, as a result of suppressing the occurrence of ringing in the power supply voltage Vcc1 supplied to the amplifying element 11 of the first stage, variations of the power supply voltage Vcc1 in the case of supplying the power supply voltage Vcc of multiple discrete voltage levels can be regulated. Using the power amplification method according to the first exemplary embodiment can thus reduce the quality degradation of a radio-frequency signal in the case of supplying the power supply voltage Vcc of multiple discrete voltage levels.

In the first exemplary embodiment, the supply mode of the power supply voltage Vcc is not limited to the APT mode and may be the ET mode.

### Second Embodiment

A second exemplary embodiment will now be described below.

The second exemplary embodiment is different from the first exemplary embodiment in that a power supply voltage Vcc having a continuously changing voltage level may be input into the external power supply terminal. That is, the power amplifier circuit according to the second exemplary embodiment operates in the analog ET mode as well as in the APT mode. Hereinafter, the second exemplary embodiment will be described by mainly referring to the points different from the first exemplary embodiment while an explanation of the same points is omitted or simplified.

### 2.1 Circuit Configurations of Power Amplifier Circuit 201 and Power Supply Circuit 205

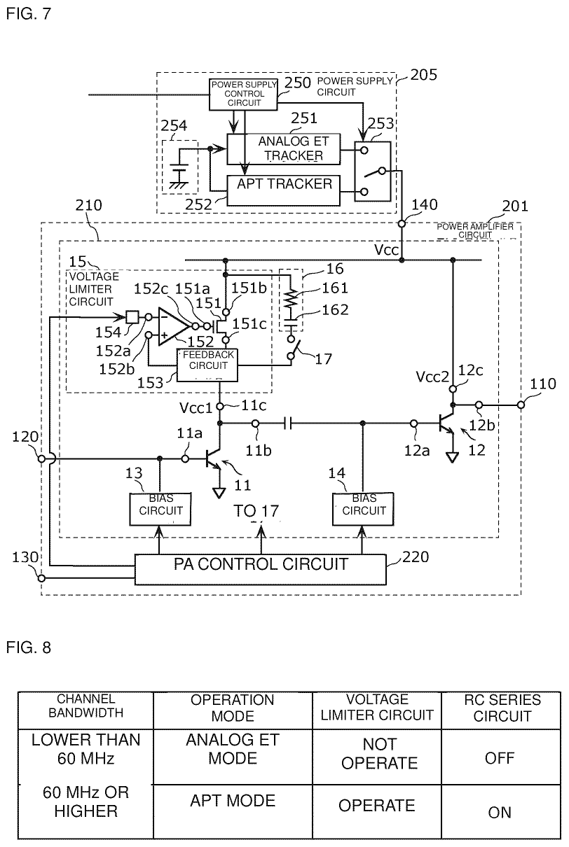

The circuit configurations of a power amplifier circuit 201 and a power supply circuit 205 according to the second exemplary embodiment will first be discussed below with reference to FIG. 7. FIG. 7 is a circuit diagram of the power amplifier circuit 201 and the power supply circuit 205 according to the second exemplary embodiment.

The power amplifier circuit 201 and the power supply circuit 205 shown in FIG. 7 are provided in the communication device 7 and the radio-frequency module 6 according to the first exemplary embodiment, instead of the power amplifier circuit 1 and the power supply circuit 5.

### 2.1.1. Circuit Configuration of Power Supply Circuit 205

The circuit configuration of the power supply circuit 205 will first be discussed below with reference to FIG. 7.

As illustrated in FIG. 7, the power supply circuit 205 includes a power supply control circuit 250, an analog ET tracker 251, an APT tracker 252, a switch 253, and a power supply 254.

Based on average output power of a radio-frequency signal, the power supply control circuit 250 controls the APT tracker 252 to cause it to select the voltage level of a power supply voltage Vcc to be used in the power amplifier circuit 201 from among multiple discrete voltage levels generated in the APT tracker 252. Based on the envelope signal of a radio-frequency input signal obtained from the BBIC 4, the power supply control circuit 250 controls the analog ET tracker 251 to cause it to continuously change the voltage level of a power supply voltage Vcc generated in the analog ET tracker 251. The power supply control circuit 250 may control the power level of the analog ET tracker 251 so that the power level becomes a linear function of the power amplitude of a radio-frequency input signal. The power supply control circuit 250 also switches the connection of the switch 253 based on the channel bandwidth of a radio-frequency signal to be input into the power amplifier circuit 201. The power supply control circuit 250 may be provided in the RFIC 3 instead of in the power supply circuit 205.

The analog ET tracker 251 generates a power supply voltage of a continuously changing voltage level, based on the voltage of the power supply 254. More specifically, the APT tracker 251, which includes a voltage retaining circuit that retains a voltage whose level is variable, changes the level of the voltage retained in the voltage retaining circuit and outputs the resulting power supply voltage.

The APT tracker 252 generates a power supply voltage of multiple discrete voltage levels, based on the voltage of the power supply 254. More specifically, the APT tracker 252, which includes plural voltage retaining circuits that retain individual voltage levels different from each other, selects one of the voltage retaining circuits and outputs the power supply voltage of the voltage level retained by the selected voltage retaining circuit.

The switch 253 has a common terminal connected to the external power supply terminal 140, a first selection terminal connected to the analog ET tracker 251, and a second selection terminal connected to the APT tracker 252. The switch 253 switches between the connection of the analog ET tracker 251 to the external power supply terminal 140 and the connection of the APT tracker 252 to the external power supply terminal 140.

With this configuration, the power supply circuit 205 is able to select as a power supply voltage Vcc one of a voltage whose level is discretely variable (digital voltage) and a voltage whose level is continuously variable (analog voltage) and output the selected voltage. The mode in which the power supply circuit 205 outputs a voltage of a discretely variable level as the power supply voltage Vcc is the APT mode shown in FIG. 3B. The mode in which the power supply circuit 205 outputs a voltage of a continuously variable level as the power supply voltage Vcc is the analog ET mode shown in FIG. 3A.

### 2.1.2 Circuit Configuration of Power Amplifier Circuit 201

The circuit configuration of the power amplifier circuit 201 will now be described below with reference to FIG. 7.

As illustrated in FIG. 7, the power amplifier circuit 201 includes a power amplifier 210 and a PA control circuit 220. The power amplifier 210 is different from the power amplifier 10 shown in FIG. 2 in that it also includes a switch 17.

The switch 17 is an example of a first switch connected in series with the RC series circuit 16. As illustrated in FIG. 7, the switch 17 is connected between an end of the capacitor 162 which is not connected to the resistor 161 and a path connecting the output terminal 151c of the transistor 151 and the power supply terminal 11c of the amplifying element 11. Alternatively, the switch 17 may be connected between an end of the resistor 161 which is not connected to the capacitor 162 and a path connecting the external power supply terminal 140 and the input terminal 151b of the transistor 151. The switch 17 is constituted by an SPST (Single-Pole Single-Throw) switch circuit, for example.

The switch 17 controls ON and OFF (disconnection) of the parallel connection between the RC series circuit 16 and the voltage limiter circuit 15. More specifically, the switch 17 is turned ON (conduction state) to connect the RC series circuit 16 in parallel with the voltage limiter circuit 15. The switch 17 is turned OFF (non-conduction state) to disconnect the RC series circuit 16 from the voltage limiter circuit 15. The switch 17 is controlled by the PA control circuit 220.

The PA control circuit 220 performs switching between ON (conduction state) and OFF (non-conduction state) of the switch 17 in addition to executing processing performed by the PA control circuit 20 of the first exemplary embodiment. Specific switching conditions will be explained later.

### 2.2 Operation of Power Amplifier Circuit 201

The operation of the power amplifier circuit 201 will now be described below with reference to FIG. 8.

FIG. 8 is a table illustrating the operation of the power amplifier circuit 201 according to the second exemplary embodiment. The power amplifier circuit 201 uses the analog ET mode and the APT mode as operation modes. As shown in FIG. 8, the analog ET mode and the APT mode are switched therebetween based on the channel bandwidth.

When the channel bandwidth is smaller than a first threshold, the power amplifier circuit 201 operates in the analog ET mode. The first threshold is 60 MHz, for example. When the channel bandwidth is relatively small, the power supply voltage Vcc can follow a change in the envelope of a modulated signal, as shown in FIG. 3A. In contrast, when the channel bandwidth is relatively large, the power supply voltage Vcc is unable to follow a change in the envelope of a modulated signal. In other words, when the channel bandwidth is relatively large, the amplitude change of the power supply voltage Vcc tends to delay with respect to a change in the envelope of a modulated signal.

For this reason, in the second exemplary embodiment, when the channel bandwidth is larger than or equal to the first threshold, the power amplifier circuit 201 operates in the APT mode. In the APT mode, multiple discrete voltage levels can be varied therebetween with the use of a switch. With high-speed switching between multiple discrete voltage levels using the switch, the amplitude change of the power supply voltage Vcc can follow a change in the envelope of a modulated signal.

When the channel bandwidth is equal to the first threshold, the power amplifier circuit 201 may operate in the analog ET mode instead of in the APT mode. That is, when the channel bandwidth is smaller than or equal to the first threshold, the power amplifier circuit 201 may operate in the analog ET mode, and when the channel bandwidth is larger than the first threshold, the power amplifier circuit 201 may operate in the APT mode.

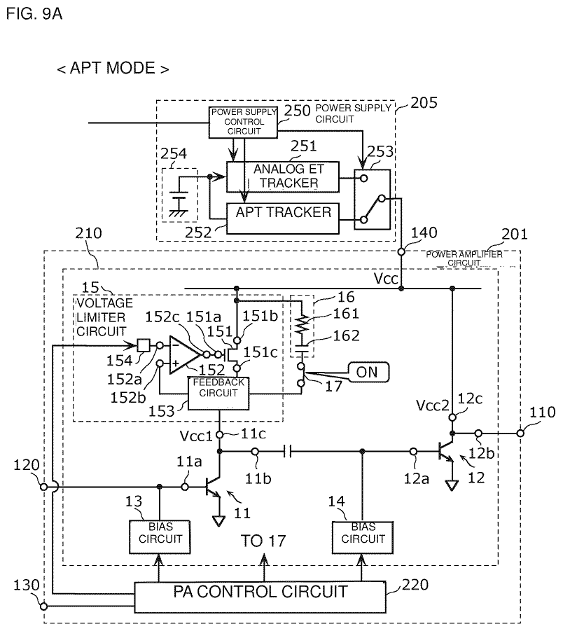

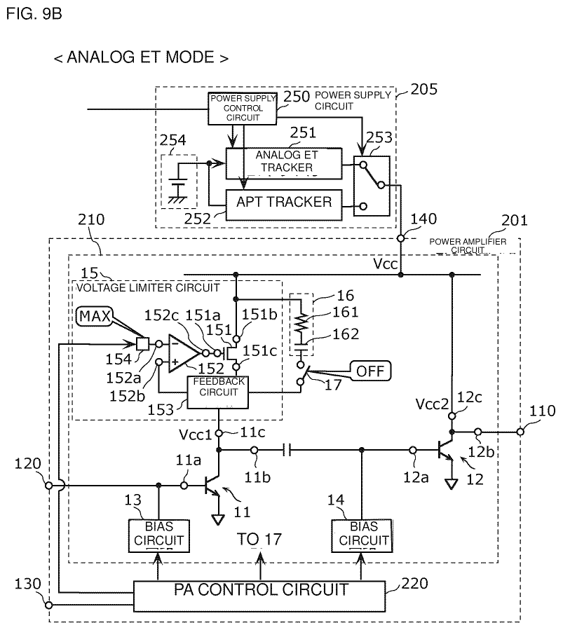

FIG. 9A is a circuit diagram of the power amplifier circuit 201 operating in the APT mode. In the APT mode, the external power supply terminal 140 receives a power supply voltage Vcc variable to multiple discrete voltage levels from the power supply circuit 5. As shown in FIG. 9A, the PA control circuit 220 turns ON the switch 17. The switch 17 thus enters the conduction state so as to connect the RC series circuit 16 in parallel with the voltage limiter circuit 15. With this operation, the circuit configuration of the power amplifier circuit 201 becomes equal to that of the power amplifier circuit 1 of the first exemplary embodiment. In the APT mode, therefore, the quality degradation of a radio-frequency output signal in the case of supplying a power supply voltage Vcc of multiple discrete voltage levels can be reduced, as in the first exemplary embodiment.

FIG. 9B is a circuit diagram of the power amplifier circuit 201 operating in the analog ET mode. As illustrated in FIG. 9B, the PA control circuit 220 sends a control signal to the control terminal 154 of the voltage limiter circuit 15 so as to set the upper limit value of the voltage limiter circuit 15 to be the maximum value (5.0 V, for example) of the power supply voltage Vcc. With this operation, the voltage limiter circuit 15 is no longer in operation and the power supply voltage Vcc received via the external power supply terminal 140 is not restricted and is supplied to the power supply terminal 11c of the amplifying element 11.

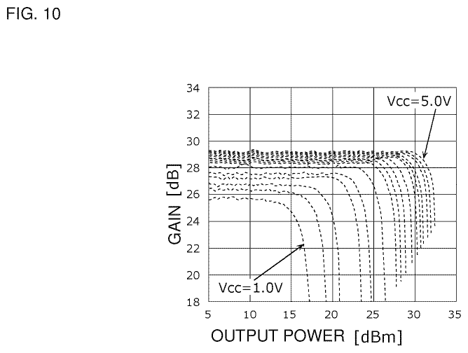

FIG. 10 is a graph illustrating the gain of the power amplifier circuit 201 operating in the analog ET mode. In FIG. 10, the horizontal axis indicates output power of the power amplifier circuit 201, and the vertical axis indicates the gain of the power amplifier circuit 201.

In the analog ET mode, the power supply voltage Vcc is determined based on the envelope signal (square root of (i²+Q²)). In FIG. 10, the gain characteristics are indicated by the broken line in accordance with the individual voltage levels of the power supply voltage Vcc. In the analog ET mode, ideally, the difference in the gain characteristics is considerably small, thereby containing the gain variations to be sufficiently small. Hence, the quality degradation of a radio-frequency output signal can be reduced.

In the analog ET mode, the PA control circuit 220 turns OFF the switch 17. The switch 17 enters the non-conduction state so as to disconnect the RC series circuit 16 from the voltage limiter circuit 15. In the analog ET mode, there is no sharp rise of a power supply voltage, so that ringing does not occur. As a result of disconnecting the RC series circuit 16 from the path of the power supply voltage Vcc1 (=power supply voltage Vcc), the influence on the power supply voltage Vcc1 can be diminished.

### 2.3 Exemplary Advantages and Others

As described above, in a power amplifier circuit 201 according to the second exemplary embodiment, a power amplifier 210 includes a switch 17 connected in series with the RC series circuit 16.

With this configuration, as a result of switching between ON and OFF of the switch 17, the connection relationship between the voltage limiter circuit 15 and the RC series circuit 16 can be changed. For example, the parallel connection between the voltage limiter circuit 15 and the RC series circuit 16 can be disconnected. When the voltage limiter circuit 15 is not operated, the RC series circuit 16 is disconnected from the voltage limiter circuit 15, thereby stabilizing the power supply voltage Vcc1 (=power supply voltage Vcc). In this manner, controlling ON and OFF of the switch 17 can reduce the quality degradation of a radio-frequency output signal.

Moreover, for example, when the channel bandwidth of a radio-frequency signal is smaller than a first threshold, the switch 17 is turned OFF. When the channel bandwidth is greater than the first threshold, the switch 17 is turned ON.

With this configuration, when the channel bandwidth is relatively small, the RC series circuit 16 can be disconnected from the voltage limiter circuit 15, thereby stabilizing the power supply voltage Vcc1 (=power supply voltage Vcc). When the channel bandwidth is relatively large, the RC series circuit 16 can be connected in parallel with the voltage limiter circuit 15. The quality degradation of a radio-frequency output signal in the case of supplying a power supply voltage Vcc of multiple discrete voltage levels can thus be reduced, as in the first exemplary embodiment.

Additionally, for example, when the power supply voltage Vcc received by the external power supply terminal 140 from the power supply circuit 205 is a continuously changing voltage (analog ET mode), the switch 17 is turned OFF. When the power supply voltage Vcc received by the external power supply terminal 140 from the power supply circuit 205 is a voltage variable to multiple discrete voltage levels (APT mode), the switch 17 is turned ON.

With this configuration, in the case of the analog ET mode, the RC series circuit 16 can be disconnected from the voltage limiter circuit 15, thereby stabilizing the power supply voltage Vcc1 (=power supply voltage Vcc). In the case of the APT mode, the RC series circuit 16 can be connected in parallel with the voltage limiter circuit 15. The quality degradation of a radio-frequency output signal in the case of supplying a power supply voltage Vcc of multiple discrete voltage levels can thus be reduced, as in the first exemplary embodiment.

In the second exemplary embodiment, the supply mode of the power supply voltage Vcc is not limited to the analog ET mode or the APT mode and may be an ET mode different from the analog ET mode.

### Third Embodiment

A third exemplary embodiment will now be described below.

The third exemplary embodiment is different from the second exemplary embodiment in that it includes plural RC series circuit. Hereinafter, the third exemplary embodiment will be described by mainly referring to the points different from the second exemplary embodiment while an explanation of the same points is omitted or simplified.

### 3.1 Circuit Configuration of Power Amplifier Circuit 301

The circuit configuration of a power amplifier circuit 301 according to the third exemplary embodiment will first be described below with reference to FIG. 11. FIG. 11 is a circuit diagram of the power amplifier circuit 301 according to the third exemplary embodiment.

The power amplifier circuit 301 shown in FIG. 11 is provided in the communication device 7 and the radio-frequency module 6 of the second exemplary embodiment, instead of the power amplifier circuit 201. The power amplifier circuit 301 may alternatively be provided in the communication device 7 and the radio-frequency module 6 of the first exemplary embodiment, instead of the power amplifier circuit 1.

As illustrated in FIG. 11, the power amplifier circuit 301 includes a power amplifier 310 and a PA control circuit 320. The power amplifier 310 is different from the power amplifier 10 shown in FIG. 2 in that it also includes an RC series circuit 18 and a switch 19. The switch 17 is the same as the switch 17 of the second exemplary embodiment.

The RC series circuit 18 is an example of a second RC series circuit and is connected in parallel with the voltage limiter circuit 15. The RC series circuit 18 is also called an RC snubber circuit.

The RC series circuit 18 includes a resistor 181 and a capacitor 182. The resistor 181 and the capacitor 182 are connected in series with each other. For example, the resistor 181 is connected at one end to the path connecting the external power supply terminal 140 and the input terminal 151b of the transistor 151 and is connected at the other end to one end of the capacitor 182. The other end of the capacitor 182 is connected to the path connecting the output terminal 151c of the transistor 151 and the power supply terminal 11c of the amplifying element 11.

The RC series circuits 16 and 18 are connected in parallel with each other. The time constant of the RC series circuit 18 is greater than that of the RC series circuit 16. More specifically, at least one of the resistance value and the capacitance value of the RC series circuit 18 is greater than that of the RC series circuit 16. For example, the resistance value R_{SNB2} of the resistor 181 of the RC series circuit 18 is greater than the resistance value R_{SNB1} of the resistor 161 of the RC series circuit 16. For example, the capacitance value C_{SNB2} of the capacitor 182 of the RC series circuit 18 is greater than the capacitance value C_{SNB1} of the capacitor 162 of the RC series circuit 16.

The switch 19 is connected in series with the RC series circuit 18. As illustrated in FIG. 11, the switch 19 is connected between an end of the capacitor 182 which is not connected to the resistor 181 and the path connecting the output terminal 151c of the transistor 151 and the power supply terminal 11c of the amplifying element 11. Alternatively, the switch 19 may be connected between an end of the resistor 181 which is not connected to the capacitor 182 and the path connecting the external power supply terminal 140 and the input terminal 151b of the transistor 151. The switch 19 is constituted by an SPST switch circuit, for example.

The switch 19 is turned ON to connect the RC series circuit 18 in parallel with the voltage limiter circuit 15. The switch 19 is turned OFF to disconnect the RC series circuit 18 from the voltage limiter circuit 15. The switch 19 is controlled by the PA control circuit 320.

The switch 19 forms a second switch, which selectively connects the RC series circuit 16 to the voltage limiter circuit 15 or disconnects the RC series circuit 16 from the voltage limiter circuit 15 and also selectively connects the RC series circuit 18 to the voltage limiter circuit 15 or disconnects the RC series circuit 18 from the voltage limiter circuit 15, together with the switch 17. The second switch may be constituted by an SPDT switch circuit, instead of by the two switches 17 and 19.

The PA control circuit 320 performs switching between ON (conduction state) and OFF (non-conduction state) of the switches 17 and 19 in addition to executing processing performed by the PA control circuit 20 of the first exemplary embodiment. Specific switching conditions will be explained later.

### 3.2 Operation of Power Amplifier Circuit 301

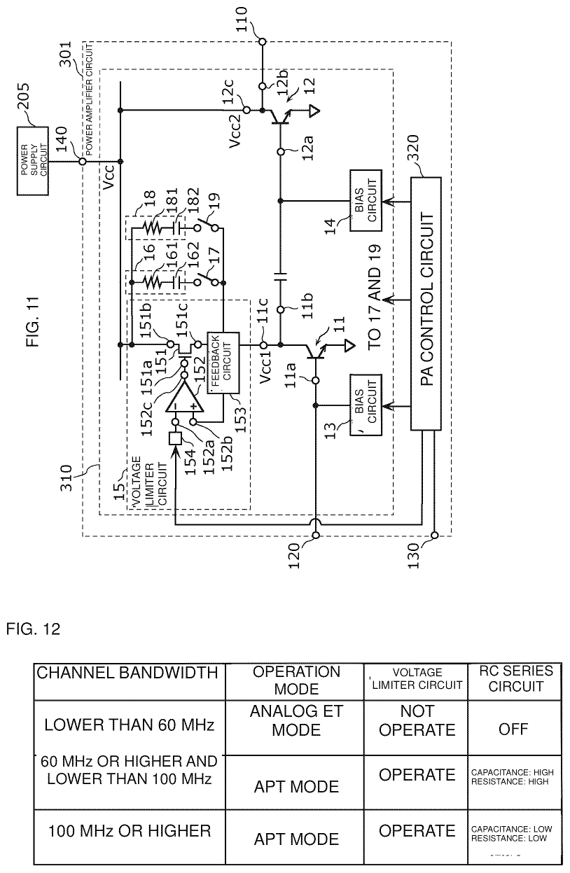

The operation of the power amplifier circuit 301 will now be described below with reference to FIG. 12.

FIG. 12 is a table illustrating the operation of the power amplifier circuit 301 according to the third exemplary embodiment. The power amplifier circuit 301 uses the analog ET mode and the APT mode as operation modes. The analog ET mode and the APT mode are switched therebetween in the same manner as the second exemplary embodiment. In the third exemplary embodiment, when the power amplifier circuit 301 is operating in the APT mode, the operation of the power amplifier circuit 301 can be switched based on the channel bandwidth.

When the channel bandwidth is smaller than a second threshold, the power amplifier circuit 301 connects the RC series circuit 18 having a large time constant in parallel with the voltage limiter circuit 15. The second threshold is greater than the first threshold used for switching between the analog ET mode and the APT mode. The second threshold is 100 MHz, for example.

In the third exemplary embodiment, when the channel bandwidth is greater than or equal to the first threshold (60 MHz, for example) and is smaller than the second threshold, the power amplifier circuit 301 connects the RC series circuit 18 in parallel with the voltage limiter circuit 15. More specifically, the switch 19 is turned ON and the switch 17 is turned OFF. This connects the RC series circuit 18 in parallel with the voltage limiter circuit 15 and disconnects the RC series circuit 16 from the voltage limiter circuit 15.

When the channel bandwidth is relatively small, the frequency of variations of the power supply voltage Vcc1 is low. Connecting the RC series circuit 18 having a large time constant in parallel can thus suppress the occurrence of ringing.

When the channel bandwidth is larger than or equal to the second threshold, the power amplifier circuit 301 connects the RC series circuit 16 having a small time constant in parallel with the voltage limiter circuit 15. More specifically, the switch 17 is turned ON and the switch 19 is turned OFF. This connects the RC series circuit 16 in parallel with the voltage limiter circuit 15 and disconnects the RC series circuit 18 from the voltage limiter circuit 15.

When the channel bandwidth is relatively large, the frequency of variations of the power supply voltage Vcc1 is high. Connecting the RC series circuit 16 having a small time constant in parallel can thus suppress the occurrence of ringing.

When the channel bandwidth is equal to the second threshold, the power amplifier circuit 301 may connect, not the RC series circuit 16, but the RC series circuit 18, in parallel with the voltage limiter circuit 15. That is, when the channel bandwidth is smaller than or equal to the second threshold, the power amplifier circuit 301 may connect the RC series circuit 18 in parallel with the voltage limiter circuit 15, and when the channel bandwidth is larger than the second threshold, the power amplifier circuit 301 may connect the RC series circuit 16 in parallel with the voltage limiter circuit 15.

In the third exemplary embodiment, when the channel bandwidth is smaller than the first threshold, the power amplifier circuit 301 operates in the analog ET mode and does not operate the voltage limiter circuit 15. In this case, the switches 17 and 19 are both turned OFF so as to disconnect the RC series circuits 16 and 18 from the voltage limiter circuit 15. In the analog ET mode, the influence on the power supply voltage Vcc1 can thus be diminished, as in the second exemplary embodiment. In the third exemplary embodiment, the application of the analog ET mode may be omitted.

### 3.3 Modified Examples

A modified example of the third exemplary embodiment will be explained below.

In the third exemplary embodiment, plural RC series circuits are provided, and the connection of each of the RC series circuits to the voltage limiter circuit 15 is switched and the disconnection of each of the RC series circuits from the voltage limiter circuit 15 is switched, thereby changing the time constant of the RC series circuit connected to the voltage limiter circuit 15. In contrast, in the present modified example, an RC series circuit whose resistance value and/or capacitance value are variable, that is, an RC series circuit whose time constant is variable, is provided.

### 3.3.1 Circuit Configuration

FIG. 13 is a circuit diagram of a power amplifier circuit 301A according to the present modified example. The power amplifier circuit 301A shown in FIG. 13 includes a power amplifier 310A and a PA control circuit 320A. The power amplifier 310A is different from the power amplifier 310 shown in FIG. 11 in that it includes an RC series circuit 16A instead of the RC series circuit 16.

The RC series circuit 16A is an RC series circuit whose time constant is variable. As illustrated in FIG. 13, the RC series circuit 16A includes a variable resistor 161A and a variable capacitor 162A. The resistance value of the variable resistor 161A and the capacitance value of the variable capacitor 162A are changed by the PA control circuit 320A.

The RC series circuit 16A may include the variable resistor 161A and a capacitor having a fixed capacitance value. Alternatively, the RC series circuit 16A may include a resistor having a fixed resistance value and a capacitor whose capacitance is variable.

The PA control circuit 320A controls the time constant of the RC series circuit 16A in addition to executing processing performed by the PA control circuit 220 of the second exemplary embodiment. The specific control operation will be discussed below.

### 3.3.2 Operation

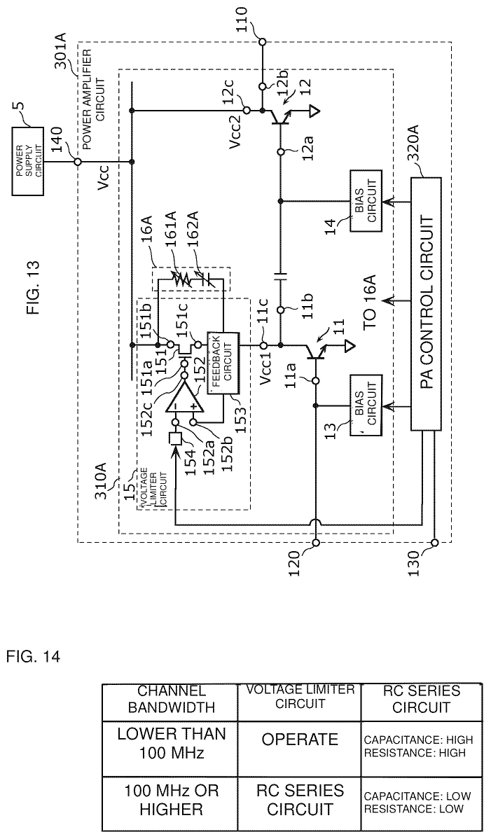

The operation of the power amplifier circuit 301A will now be discussed below with reference to FIG. 14.

FIG. 14 is a table illustrating the operation of the power amplifier circuit 301A according to the present modified example. The power amplifier circuit 301A uses, not the analog ET mode, but the APT mode, as in the first exemplary embodiment.

When the channel bandwidth is smaller than a third threshold, the time constant of the RC series circuit 16A of the power amplifier circuit 301A is increased. The third threshold is 100 MHz, for example. When the channel bandwidth is smaller than 100 MHz, the RC series circuit 16A increases at least one of the resistance value of the variable resistor 161A and the capacitance value of the variable capacitor 162A.

When the channel bandwidth is larger than or equal to the third threshold, the time constant of the RC series circuit 16A of the power amplifier circuit 301A is decreased. When the channel bandwidth is smaller than 100 MHz, the RC series circuit 16A increases at least one of the resistance value of the variable resistor 161A and the capacitance value of the variable capacitor 162A.

With this operation, the occurrence of ringing can be effectively suppressed in accordance with the magnitude of the channel bandwidth, as in the third exemplary embodiment.

### 3.4 Exemplary Advantages and Others

As described above, a power amplifier circuit 301 according to the third exemplary embodiment includes an RC series circuit 18 and switches 17 and 19. The RC series circuit 18 is connected in parallel with the voltage limiter circuit 15 and has a time constant larger than that of the RC series circuit 16. The switch 17 selectively connects the RC series circuit 16 in parallel with the voltage limiter circuit 15 or disconnects the RC series circuit 16 from the voltage limiter circuit 15. The switch 19 selectively connects the RC series circuit 18 in parallel with the voltage limiter circuit 15 or disconnects the RC series circuit 18 from the voltage limiter circuit 15.

With this configuration, the RC series circuit to be connected in parallel with the voltage limiter circuit 15 can be changed by using the switches. A suitable RC series circuit is selected in accordance with the operation mode or the channel bandwidth, thereby enhancing the effect of suppressing the occurrence of ringing.

Additionally, for example, when the channel bandwidth is smaller than a second threshold, the switches 17 and 19 connect the RC series circuit 18 having a large time constant in parallel with the voltage limiter circuit 15. When the channel bandwidth is greater than the second threshold, the switches 17 and 19 connect the RC series circuit 16 having a small time constant in parallel with the voltage limiter circuit 15.

This can enhance the effect of suppressing the occurrence of ringing.

Three or more RC series circuits may be connected in parallel with the voltage limiter circuit 15. One RC series circuit selected from the three or more RC series circuits may be connected in parallel with the voltage limiter circuit 15 by using a switch. When plural RC series circuits are provided, two or more RC series circuits may be connected in parallel with the voltage limiter circuit 15 at the same time.

In a power amplifier circuit 301A according to the above-described modified example, the resistor of an RC series circuit 16A is a variable resistor 161A.

With this configuration, the time constant of the RC series circuit 16A can be adjusted in accordance with the operation mode or the channel bandwidth, thereby enhancing the effect of suppressing the occurrence of ringing. Additionally, the variable resistor 161A is easy to design so that it can be easily mounted.

Furthermore, for example, the capacitor of the RC series circuit 16A is a variable capacitor 162A.

With this configuration, the time constant of the RC series circuit 16A can be adjusted in accordance with the operation mode or the channel bandwidth, thereby enhancing the effect of suppressing the occurrence of ringing.

Additionally, for example, when the channel bandwidth is smaller than a third threshold, the time constant of the RC series circuit 16A is increased. When the channel bandwidth is greater than the third threshold, the time constant of the RC series circuit 16A is decreased.

With this configuration, the time constant of the RC series circuit 16A can be adjusted in accordance with the channel bandwidth, thereby enhancing the effect of suppressing the occurrence of ringing.

In the third exemplary embodiment, the supply mode of the power supply voltage Vcc is not limited to the analog ET mode or the APT mode and may be an ET mode different from the analog ET mode.

### EXAMPLES

Examples of the radio-frequency modules according to the above-described exemplary embodiments and modified examples will now be described below.

### 4.1 First Example

A radio-frequency module according to a first example will first be discussed below. The radio-frequency module according to the first example is a double-sided-mounting module.

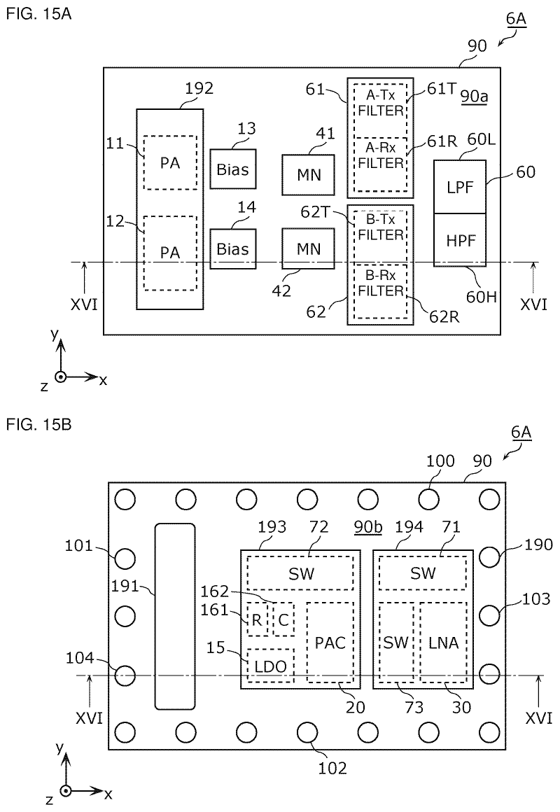

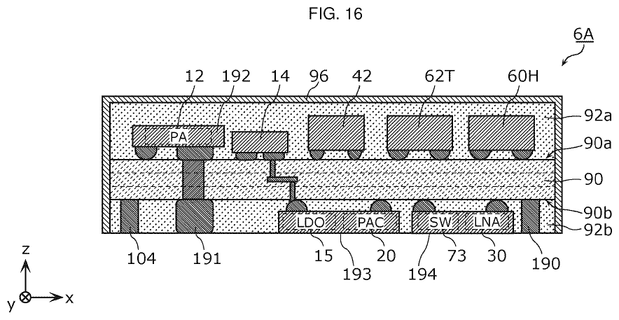

FIG. 15A is a plan view of a radio-frequency module 6A according to the first example when a main surface 90a of a module laminate 90 and the inside of the module laminate 90 are seen through from the positive side of the z axis. FIG. 15B is a plan view of the radio-frequency module 6A according to the first example when a main surface 90b of the module laminate 90 is seen through from the positive side of the z axis. FIG. 16 is a sectional view of the radio-frequency module 6A according to the first example. The cross section of the radio-frequency module 6A in FIG. 16 is a cross section taken along line XVI-XVI in FIGS. 15A and 15B.

In FIGS. 15A, 15B, and 16, for easy understanding of the positional relationships between the components, some components are appended with alphabetical characters representing the corresponding components. However, such alphabetical characters are not appended to the actual components. In FIGS. 15A, 15B, and 16, wiring for connecting plural components arranged in or on the module laminate 90 is partially omitted. In FIGS. 15A and 15B, resin members 92a and 92b for covering plural components and a shield electrode layer 96 for covering the surfaces of the resin members 92a and 92b are not shown.

In addition to the plural circuit components included in the radio-frequency module 6 shown in FIG. 1, the radio-frequency module 6A includes the module laminate 90, resin members 92a and 92b, shield electrode layer 96, plural post electrodes 190, and heat dissipation electrode 191.

The module laminate 90 has main surfaces 90a and 90b facing each other. The main surface 90a is an example of a first main surface, while the main surface 90b is an example of a second main surface. In FIGS. 15A and 15B, the module laminate 90 has a rectangular shape in a plan view but is not limited to this shape.

As the module laminate 90, a low temperature co-fired ceramics (LTCC) substrate or a high temperature co-fired ceramics (HTCC) substrate having a multilayer structure constituted by plural dielectric layers, a component-embedded board, a substrate having a redistribution layer (RDL), or a printed circuit board, for example, may be used. However, the module laminate 90 is not limited to these examples.

On the main surface 90a, an integrated circuit 192, bias circuits 13 and 14, matching circuits 41 and 42, diplexer 60, duplexers 61 and 62, and resin member 92a are disposed.

The integrated circuit 192 is an example of a second integrated circuit and includes the amplifying elements 11 and 12. Within the integrated circuit 192, the sizes of the amplifying elements 11 and 12 are different from each other. In this example, the size of the amplifying element 12 is smaller than that of the amplifying element 11. The size of an amplifying element is proportional to the maximum gain and is dependent on the number of stages, the number of cells, or the number of fingers of a transistor. Accordingly, if the sizes of amplifying elements are different, the number of stages, the number of cells, or the number of fingers of a transistor of one amplifying element and that of the other amplifying element are different. The amplifying elements 11 and 12 may have the same size.

The integrated circuit 192 is made of at least one of gallium arsenide (GaAs), silicon-germanium (SiGe), and gallium nitride (GaN). The integrated circuit 192 may be constituted by a CMOS (Complementary Metal Oxide Semiconductor), and more specifically, the integrated circuit 192 may be manufactured by a SOI (Silicon on Insulator) process. The semiconductor material for the integrated circuit 192 is not limited to the above-described materials.

The bias circuits 13 and 14 are each constituted by an integrated circuit. As illustrated in FIGS. 15A and 16, the bias circuits 13 and 14 are each constituted by an integrated circuit different from the integrated circuit 192. Alternatively, the bias circuits 13 and 14 may be formed within the integrated circuit 192.

The matching circuits 41 and 42 are each constituted by a chip inductor or a chip capacitor, for example. Part of the matching circuit 41 or 42 may include an inductor and/or capacitor disposed within the module laminate 90.

As the diplexer 60 and the duplexers 61 and 62, any type of filter among surface acoustic wave (SAW) filters, bulk acoustic wave (BAW) filters, LC resonance filters, and dielectric filters, for example, may be used. The diplexer 60 and the duplexers 61 and 62 are not limited to the above-described types of filters.

The resin member 92a covers the main surface 90a and the components disposed on the main surface 90a. The resin member 92a has a function of securing the reliability, such as the mechanical strength and the moisture resistance, of the components on the main surface 90a.

On the main surface 90b, integrated circuits 193 and 194, plural post electrodes 190, heat dissipation electrode 191, and resin member 92b are disposed.

The integrated circuit 193 is an example of a first integrated circuit and includes the PA control circuit 20. In the first example, the integrated circuit 193 also includes the switch 72, voltage limiter circuit 15, and RC series circuit 16. Within the integrated circuit 193, the voltage limiter circuit 15 and the RC series circuit 16 are disposed at positions closer to the integrated circuit 192 than the PA control circuit 20 is. In one example, within the integrated circuit 193, the resistor 161 of the RC series circuit 16 is disposed at a position closer to the integrated circuit 192 than the PA control circuit 20 is. In another example, within the integrated circuit 193, the capacitor 162 of the RC series circuit 16 is disposed at a position closer to the integrated circuit 192 than the PA control circuit 20 is.

One of the resistor 161 and the capacitor 162 of the RC series circuit 16 may be disposed outside the integrated circuit 193. For example, the resistor 161 of the RC series circuit 16 may be disposed within the integrated circuit 193, while the capacitor 162 may be a chip capacitor mounted on the main surface 90a or 90b. Alternatively, the capacitor 162 may be formed by using part of a wiring pattern formed on the surface of the module laminate 90 or inside the module laminate 90.

The integrated circuit 194 includes the low-noise amplifier 30 and the switches 71 and 73. The integrated circuit 193 is located at a position closer to the integrated circuit 192 than the integrated circuit 194 is.

The integrated circuits 193 and 194 are each constituted by a CMOS, and more specifically, they are manufactured by the SOI process. Each of the integrated circuits 193 and 194 may be made of at least one of GaAs, SiGe, and GaN.

The plural post electrodes 190 are plural external connection terminals including a ground terminal as well as the antenna connection terminal 100, external input terminal 101, external output terminal 102, control terminal 103, and external power supply terminal 104 shown in FIG. 1. Each of the post electrodes 190 vertically extends from the main surface 90b and passes through the resin member 92b, and one end of each of the post electrodes 190 reaches the surface of the resin member 92b. The post electrodes 190 are connected to an input/output terminal and/or a ground terminal, for example, on a mother substrate disposed in the negative-side direction of the z axis of the radio-frequency module 6A.

Instead of the post electrodes 190, plural bump electrodes may be included in the radio-frequency module 6A. In this case, the provision of the resin member 92b in the radio-frequency module 6A may be omitted.

The heat dissipation electrode 191 is an electrode for radiating heat generated in the amplifying elements 11 and 12 to the mother substrate (not shown). In a plan view, at least part of the heat dissipation electrode 191 matches at least part of the integrated circuit 192.

The resin member 92b covers the main surface 90b and the components disposed on the main surface 90b. The resin member 92b has a function of securing the reliability, such as the mechanical strength and the moisture resistance, of the components on the main surface 90b.

The shield electrode layer 96 is a metal thin film formed by sputtering, for example. The shield electrode layer 96 covers the top surface and the side surfaces of the resin member 92a, the side surfaces of the module laminate 90, and the side surfaces of the resin member 92b. The shield electrode layer 96 is set to a ground potential and contributes to preventing outside noise from entering the circuit components forming the radio-frequency module 6A.

The layout of the components of the radio-frequency module 6A shown in FIGS. 15A, 15B, and 16 is an example and does not restrict the layout of the components. In one example, at least one of the integrated circuits 193 and 194 may be disposed on the main surface 90a. In another example, the provision of the resin members 92a and 92b and the shield electrode layer 96 in the radio-frequency module 6A may be omitted.

As described above, in the radio-frequency module 6A according to the first example, the resistor 161 of the RC series circuit 16 is disposed within the integrated circuit 193. The integrated circuit 193 includes the voltage limiter circuit 15 or the PA control circuit 20 which controls the power amplifier 10.

With this configuration, the resistor 161 of the RC series circuit 16 can be integrated into the integrated circuit 193, thereby enhancing the miniaturization of the radio-frequency module 6A.

Additionally, for example, the capacitor 162 of the RC series circuit 16 is disposed within the integrated circuit 193.

With this configuration, the capacitor 162 of the RC series circuit 16 can be integrated into the integrated circuit 193, thereby further enhancing the miniaturization of the radio-frequency module 6A.

Moreover, for example, the radio-frequency module 6A includes a module laminate 90 having main surfaces 90a and 90b. An integrated circuit 192 including the amplifying elements 11 and 12 is disposed in or on the main surface 90a. An integrated circuit 193 and the external power supply terminal 104 are disposed in or on the main surface 90b. The integrated circuit 193 includes the PA control circuit 20.

With this configuration, circuit components can be distributed over both surfaces of the module laminate 90, thereby reducing the area of the radio-frequency module 6A.

Furthermore, for example, within the integrated circuit 193, the resistor 161 of the RC series circuit 16 is disposed at a position closer to the integrated circuit 192 than the PA control circuit 20 is.

This can shorten the length of a line connecting the external power supply terminal 140 (or the external power supply terminal 104) and the resistor 161, thereby reducing loss in the power supply voltage line.

Additionally, for example, the integrated circuit 193 also includes the voltage limiter circuit 15. Within the integrated circuit 193, the voltage limiter circuit 15 is disposed at a position closer to the integrated circuit 192 than the PA control circuit 20 is.

This can shorten the length of a line connecting the external power supply terminal 140 (or the external power supply terminal 104) and the voltage limiter circuit 15, thereby reducing loss in the power supply voltage line.

### 4.2 Second Example

A radio-frequency module according to a second example will now be discussed below. The radio-frequency module according to the second example is a single-sided-mounting module.

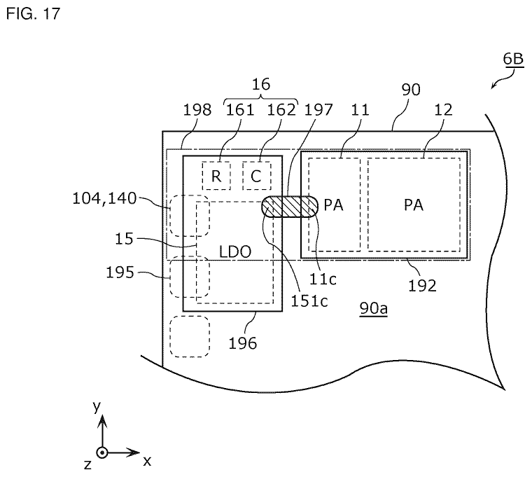

FIG. 17 is a plan view illustrating part a radio-frequency module 6B according to the second example when the main surface 90a of the module laminate 90 and the inside of the module laminate 90 are seen through from the positive side of the z axis. In FIG. 17, an integrated circuit 192 and the vicinity thereof of the radio-frequency module 6B are shown.

In addition to the plural circuit components included in the power amplifier circuit 1 shown in FIG. 1, the radio-frequency module 6B includes a module laminate 90 and plural pad electrodes 195.

On the main surface 90a, integrated circuits 192 and 196 are disposed.

The integrated circuit 192 is an example of the second integrated circuit and includes the amplifying elements 11 and 12. The integrated circuit 192 is substantially the same as the integrated circuit 192 of the first example.

The integrated circuit 196 is an example of the first integrated circuit and includes the voltage limiter circuit 15. The integrated circuit 196 also includes the RC series circuit 16.

One of the resistor 161 and the capacitor 162 of the RC series circuit 16 may be disposed outside the integrated circuit 196. For example, the resistor 161 of the RC series circuit 16 may be disposed within the integrated circuit 196, while the capacitor 162 may be a chip capacitor mounted on the main surface 90a. Alternatively, the capacitor 162 may be formed by using part of a wiring pattern formed on the surface of the module laminate 90 or inside the module laminate 90.

In the radio-frequency module 6B, the RC series circuit 16 is disposed at a position closer to the external power supply terminal 140 (or the external power supply terminal 104) than the amplifying elements 11 and 12. In this example, the external power supply terminal 140 of the power amplifier circuit 1 and the external power supply terminal 104 of the radio-frequency module 6B are integrated with each other.

For example, as shown in FIG. 17, in a plan view, the external power supply terminal 104, resistor 161, capacitor 162, and amplifying element 11 are arranged in this order. The integrated circuit 196 including the resistor 161 and the capacitor 162 and the integrated circuit 192 including the amplifying element 11 are connected to each other by wiring 197. The wiring 197 is a metal wiring laid on the main surface 90a of the module laminate 90, for example. One end of the wiring 197 is the output terminal 151c of the transistor 151 (see FIG. 2), while the other end of the wiring 197 is the power supply terminal 11c of the amplifying element 11. Disposing the external power supply terminal 104, resistor 161, capacitor 162, and amplifying element 11 in this order can shorten a wiring path from the external power supply terminal 104 to the amplifying element 11.

On the main surface 90b, the plural pad electrodes 195 are arranged. The pad electrodes 195 are plural external connection terminals including a ground terminal as well as the external power supply terminal 140 (external power supply terminal 104). The pad electrodes 195 are connected to an input/output terminal and/or a ground terminal, for example, on a mother substrate disposed in the negative-side direction of the z axis of the radio-frequency module 6B. Instead of the pad electrodes 195, plural bump electrodes or plural post electrodes may be included in the radio-frequency module 6B.

In the second example, in a plan view of the main surface 90a, the RC series circuit 16 is disposed within a smallest rectangular region 198. The smallest rectangular region 198 is a rectangular region which circumscribes the external power supply terminal 140 and the integrated circuit 192 and which minimizes the area. In FIG. 17, the smallest rectangular region 198 is indicated by the long dashed dotted line. To avoid the overlapping of lines, the smallest rectangular region 198 is illustrated slightly larger for easy representation.

At least part of the voltage limiter circuit 15 is also disposed within the smallest rectangular region 198. For example, a transistor 151 (not shown) included in the voltage limiter circuit 15 is disposed within the smallest rectangular region 198.

The layout of the components of the radio-frequency module 6B shown in FIG. 17 is an example and does not restrict the layout of the components. In one example, the radio-frequency module 6B may include a resin member 92a and/or a resin member 92b and may include a shield electrode layer 96.

As described above, the radio-frequency module 6B according to the second example includes a module laminate 90 having main surfaces 90a and 90b. The power amplifier 10 is disposed in or on the main surface 90a. The external power supply terminal 140 (external power supply terminal 104) is disposed in or on the main surface 90b. The RC series circuit 16 is disposed at a position closer to the external power supply terminal 140 than the amplifying elements 11 and 12.

This can shorten the length of a line connecting the external power supply terminal 140 and the resistor 161, thereby reducing loss in the power supply voltage line.

Additionally, for example, in a plan view of the main surface 90a, the RC series circuit 16 is disposed within a smallest rectangular region 198 which circumscribes the external power supply terminal 104 and a second integrated circuit 192 including the amplifying elements 11 and 12.

With this configuration, the RC series circuit 16 and the integrated circuit 192 can be disposed close to each other, thereby enhancing the miniaturization of the radio-frequency module 6B.

Moreover, for example, at least part of the voltage limiter circuit 15 is disposed within the smallest rectangular region 198.

With this configuration, the RC series circuit 16, at least part of the voltage limiter circuit 15, and the integrated circuit 192 can be disposed close to each other, thereby enhancing the miniaturization of the radio-frequency module 6B.

In each of the first and second examples, if plural RC series circuits are provided, they may be disposed within one integrated circuit. Only the resistor of each of the plural RC series circuits may be disposed within the integrated circuit. Among the resistors and the capacitors included in the plural RC series circuits, only one resistor and/or only one capacitor may be disposed within the integrated circuit or only one resistor and/or only one capacitor may be disposed outside the integrated circuit.

### Others

The power amplifier circuit and the power amplification method according to the present disclosure have been discussed above through illustration of the above-described exemplary embodiments. However, the disclosure is not restricted to the above-described exemplary embodiments.

In one example, in the circuit configurations of the power amplifier circuits, radio-frequency circuits, and communication devices according to the above-described exemplary embodiments, another circuit element and another wiring may be inserted onto a path connecting circuit elements and/or onto a path connecting signal paths illustrated in the drawings.

In another example, as the amplifying element of the second stage, plural amplifying elements forming a differential amplifier, a Doherty amplifier, or an in-phase amplifier, for example, may be used.

In another example, the radio-frequency module may include plural external power supply terminals, and the power amplifier circuit may include plural external power supply terminals. The plural external power supply terminals may be connected to one power supply circuit or to different power supply circuits.

For example, the power amplifier circuit may include a first external power supply terminal that receives a voltage to be supplied to the power supply terminal of the amplifying element of the first stage and a second external power supply terminal that receives a voltage to be supplied to the power supply terminal of the amplifying element of the second stage. A voltage limiter circuit to which one or more RC series circuits are parallel-connected is connected between the first external power supply terminal and the power supply terminal of the amplifying element of the first stage. The voltage limiter circuit is not connected between the second external power supply terminal and the power supply terminal of the amplifying element of the second stage. For example, the second external power supply terminal and the power supply terminal of the amplifying element of the second stage are directly connected to each other. This eliminates the need to arrange the routing of wiring from one of the external power supply terminals within the power amplifier circuit. This shortens the line length, thereby reducing loss in the power supply voltage line.

Other exemplary embodiments obtained by making various modifications to the above-described exemplary embodiments by those skilled in the art and other exemplary embodiments implemented by combining certain elements and certain functions in the above-described exemplary embodiments without departing from the scope and spirit of the disclosure are also encompassed in the disclosure.

### INDUSTRIAL APPLICABILITY

The present disclosure can be widely used in communication equipment, such as mobile phones, as a power amplifier circuit or a radio-frequency circuit disposed in a multiband-support front-end section.

### REFERENCE SIGNS LIST

1, 201, 301, 301A power amplifier circuit
2 antenna
3 RFIC
4 BBIC
5, 205 power supply circuit
6, 6A, 6B radio-frequency module
7 communication device
10, 210, 310, 310A power amplifier
11, 12, 152 amplifying element
11a, 12a, 151b, 152a, 152b input terminal
11b, 12b, 151c, 152c output terminal
11c, 12c power supply terminal
13, 14 bias circuit
15 voltage limiter circuit
16, 16A, 18 RC series circuit
17, 19, 71, 72, 73, 253 switch
20, 220, 320, 320A PA control circuit
30 low-noise amplifier
41, 42 matching circuit
60 diplexer
60H high pass filter
60L low pass filter
61, 62 duplexer
61R, 62R receive filter
61T, 62T transmit filter
71a, 71b, 71c, 72a, 72b, 72c, 73a, 73b, 73c terminal
90 module laminate
90a, 90b main surface
92a, 92b resin member
96 shield electrode layer
100 antenna connection terminal
101, 120 external input terminal
102, 110 external output terminal
103, 130 control terminal
104, 140 external power supply terminal
151 transistor
151a, 154 control terminal
153 feedback circuit
161, 181 resistor
161A variable resistor
162, 182 capacitor
162A variable capacitor
190 post electrode
191 heat dissipation electrode
192, 193, 194, 196 integrated circuit
195 pad electrode
197 wiring
198 smallest rectangular region
250 power supply control circuit
251 analog ET tracker
252 APT tracker
254 power supply

1. A power amplifier circuit comprising:
an external input terminal and an external output terminal;
a power amplifier; and
at least one external power supply terminal that receives, from a power supply circuit, a power supply voltage to be supplied to the power amplifier, wherein
the power amplifier includes
a first amplifying element including a first input terminal, a first output terminal, and a first power supply terminal,
a second amplifying element including a second input terminal, a second output terminal, and a second power supply terminal,
a first circuit that restricts the power supply voltage to a predetermined range and outputs the restricted power supply voltage, and
a first RC series circuit connected in parallel with the first circuit,
the first input terminal is connected to the external input terminal,
the first output terminal is connected to the second input terminal,
the second output terminal is connected to the external output terminal,
the first power supply terminal is connected to the at least one external power supply terminal via the first circuit, and
the second power supply terminal is connected to the at least one external power supply terminal.

2. A power amplifier circuit comprising:
an external input terminal and an external output terminal;
a power amplifier; and
at least one external power supply terminal that receives, from a power supply circuit, a power supply voltage to be supplied to the power amplifier, wherein
the power amplifier includes
a first amplifying element including a first input terminal, a first output terminal, and a first power supply terminal,
a second amplifying element including a second input terminal, a second output terminal, and a second power supply terminal,
a first circuit, and
a first RC series circuit connected in parallel with the first circuit,
the first input terminal is connected to the external input terminal,
the first output terminal is connected to the second input terminal,
the second output terminal is connected to the external output terminal,
the first power supply terminal is connected to the at least one external power supply terminal via the first circuit,
the second power supply terminal is connected to the at least one external power supply terminal, and
the first circuit includes
a third amplifying element including a third input terminal and a third output terminal,
a transistor that includes a control terminal connected to the third output terminal and that is connected between the at least one external power supply terminal and the first power supply terminal, and
a feedback circuit connected between the first power supply terminal and the third input terminal.

3. The power amplifier circuit according to claim 1, wherein the at least one external power supply terminal is a single external power supply terminal.

4. The power amplifier circuit according to claim 1, wherein the power amplifier further includes a first switch connected in series with the first RC series circuit.

5. The power amplifier circuit according to claim 4, wherein:
in a case that a channel bandwidth of a radio-frequency signal is smaller than a first threshold, the first switch is turned OFF; and
in a case that the channel bandwidth is greater than the first threshold, the first switch is turned ON.

6. The power amplifier circuit according to claim 4, wherein:
in a case that a power supply voltage received by the at least one external power supply terminal from the power supply circuit is a continuously changing voltage, the first switch is turned OFF; and
in a case that a power supply voltage received by the at least one external power supply terminal from the power supply circuit is a voltage variable to multiple discrete voltage levels, the first switch is turned ON.

7. The power amplifier circuit according to claim 1, further comprising:
a second RC series circuit that is connected in parallel with the first circuit and that has a time constant larger than a time constant of the first RC series circuit; and
a second switch that selectively connects the first RC series circuit in parallel with the first circuit or disconnects the first RC series circuit from the first circuit and that selectively connects the second RC series circuit in parallel with the first circuit or disconnects the second RC series circuit from the first circuit.

8. The power amplifier circuit according to claim 7, wherein:
in a case that a channel bandwidth of a radio-frequency signal is smaller than a second threshold, the second switch connects the second RC series circuit in parallel with the first circuit; and
in a case that the channel bandwidth is greater than the second threshold, the second switch connects the first RC series circuit in parallel with the first circuit.

9. The power amplifier circuit according to claim 1, wherein a resistor of the first RC series circuit is a variable resistor.

10. The power amplifier circuit according to claim 1, wherein a capacitor of the first RC series circuit is a variable capacitor.

11. The power amplifier circuit according to claim 9, wherein:
in a case that a channel bandwidth of a radio-frequency signal is smaller than a third threshold, a time constant of the first RC series circuit is increased; and
in a case that the channel bandwidth is greater than the third threshold, the time constant of the first RC series circuit is decreased.

12. The power amplifier circuit according to claim 1, wherein a resistor of the first RC series circuit is disposed within a first integrated circuit, the first integrated circuit including the first circuit or a control circuit which controls the power amplifier.

13. The power amplifier circuit according to claim 12, wherein a capacitor of the first RC series circuit is disposed within the first integrated circuit.

14. The power amplifier circuit according to claim 12, further comprising:
a module laminate including first and second main surfaces, the second main surface being located on a side of the module laminate opposite the first main surface, wherein
a second integrated circuit including the first and second amplifying elements is disposed in or on the first main surface,
the first integrated circuit and the at least one external power supply terminal are disposed on the second main surface, and
the first integrated circuit includes the control circuit.

15. The power amplifier circuit according to claim 14, wherein, within the first integrated circuit, the resistor of the first RC series circuit is disposed at a position closer to the second integrated circuit than the control circuit is.

16. The power amplifier circuit according to claim 14, wherein:
the first integrated circuit further includes the first circuit; and
within the first integrated circuit, the first circuit is disposed at a position closer to the second integrated circuit than the control circuit is.

17. The power amplifier circuit according to claim 1, further comprising:
a module laminate including first and second main surfaces, the second main surface being located on a side of the module laminate opposite the first main surface, wherein
the power amplifier is disposed on the first main surface,
the at least one external power supply terminal is disposed on the second main surface, and
the first RC series circuit is disposed at a position closer to the at least one external power supply terminal than the first and second amplifying elements.

18. The power amplifier circuit according to claim 17, wherein, in a plan view of the first main surface, the first RC series circuit is disposed within a smallest rectangular region, the smallest rectangular region circumscribing the at least one external power supply terminal and a second integrated circuit including the first and second amplifying elements.

19. The power amplifier circuit according to claim 18, wherein at least part of the first circuit is disposed within the smallest rectangular region.

20. A power amplification method comprising:
a first circuit configured to restrict a power supply voltage received from a power supply circuit to a predetermined range, an RC series circuit being connected in parallel with the first circuit, and being configured to supply the restricted power supply voltage to a first amplifying element;
the first amplifying element being configured to amplify a radio-frequency signal by using the power supply voltage received from the first circuit; and
a second amplifying element configured to amplify the radio-frequency signal amplified by the first amplifying element by using the power supply voltage received from the power supply circuit.
